(19) United States
(12) Patent Application Publication
(10) Pub. No.: US 2004/0063033 A1
(43) Pub. Date: Apr. 1, 2004

(54) Presensitized plate

(75) Inventor: Hisashi Hotta, Shizuoka (JP)

Correspondence Address: SUGHRUE MION, PLLC, 2100 PENNSYLVANIA AVENUE, N.W., SUITE 800, WASHINGTON, DC, 20037, US

(73) Assignee: FUJI PHOTO FILM CO., LTD.

(21) Appl. No.: 10/662,329

(22) Filed: Sep. 16, 2003

(30) Foreign Application Priority Data
Sep. 24, 2002 (JP) 2002-277295

(51) Int. Cl. G03F 7/09

(52) U.S. Cl. 430/278.1; 430/270.1; 430/302

(57) ABSTRACT

A presensitized plate which comprises an aluminum support having a grain shape in a structure in which grained structures having specified average wavelength (average aperture diameters) are superimposed, a hydrophilic layer whose thermal conductivity falls within a predetermined range and which is formed on the aluminum support, and an image recording layer of thermal positive type formed on the hydrophilic layer, exhibits a high sensitivity, has a long press life when processed into a lithographic printing plate, and is resistant to scum in the non-image area.

### BACKGROUND OF THE INVENTION

1. Field of the Invention

The present invention relates to a presensitized plate which has a high sensitivity, a long press life and an excellent scum resistance during printing (hereinafter referred to as “scum resistance”). More specifically, the invention relates to a presensitized plate having a high sensitivity, a long press life and an excellent scum resistance which is obtained by forming a hydrophilic layer with a low thermal conductivity and an image recording layer of thermal positive type on an aluminum support having a specified grain shape.

2. Description of the Related Art

In recent years, with the development of an image formation technology, a direct plate making is becoming possible by scanning a laser beam with a narrowed-down beam on the surface of the presensitized plate to directly form a lettered original, an image original or the like on the presensitized plate, dispensing with a film original.

Among these presensitized plates, a so-called thermal positive type presensitized plate which forms a positive image allowing an image recording layer to be alkali-soluble by heat obtained by generating photothermal conversion in the image recording layer by irradiation with a laser beam uses a subtle change in the intermolecular interaction of a binder in the image recording layer by a laser exposure as an image formation principle. Therefore, a difference between the alkali-soluble state in the exposed area and the non-alkali-soluble state in the unexposed area is small. For that reason, in order to obtain a practicable clear discrimination, used are means for forming an image recording layer structure with suppressed development solubility of the unexposed area by providing a surface slightly soluble layer in a developer as the top layer of the image recording layer.

If the surface slightly soluble layer is, however, damaged due to some cause, even an area which is supposed to be an image area becomes soluble in the developer. That is, practically, a printing plate is too easily damaged. For that reason, it is the status quo that handling of the presensitized plate at the time of working is difficult, since scratch-like non-image portions are generated even by a subtle touching such as hitting of the plates when handling the presensitized plate, a subtle rubbing with interleaving sheets, or a contact of fingers with plate surface. Although countermeasures are taken to lower coefficient of friction by providing a layer having a fluorine-containing surfactant or a wax on the surface of the image recording layer in order to improve damage resistance, they are not sufficient.

In the meantime, in order to increase discrimination, efficiency of development is also studied, an attempt is made to provide a hydrophilic layer by silicate treatment or an alkali-soluble undercoat layer (alkali-soluble layer) between the image recording layer and the support. According to these methods, it is certainly possible to ensure development capacity to some extent and obtain a development latitude within a practical range. However, contact characteristics between the image recording layer and the support deteriorate. In addition, if the surface shape of the support is smoothened to remove deep concave portions existent on the support surface which cause residual layers in order to increase scum resistance, press life largely deteriorates, thereby the presensitized plate becoming impractical. For this reason, a presensitized plate that is at a level that meets the requirements of easy printing, that is, excellent in press life and scum resistance has not been materialized yet.

A presensitized plate of so-called thermal positive type (thermal positive type for an infrared laser beam) where an infrared absorbent existent in the image recording layer develops a photothermal conversion action thereof to generate a heat by exposure, and a positive image is formed on the image recording layer by the generated heat which makes the exposed area alkali-soluble, has also following problems.

That is, in a thermal type image formation like this, a heat is generated by a photothermal conversion agent in a photosensitive layer by a laser beam irradiation and triggers an image formation reaction. However, since thermal conductivity of an aluminum support subjected to graining treatment and anodizing treatment is much higher than that of the image recording layer, a heat generated in the vicinity of an interface between the image recording layer and the support diffuses inside the support before it is sufficiently used for image formation. Consequently, the following problems arise in the interface between the image recording layer and the support.

In the case of the aforementioned an image recording layer of thermal positive type, if a heat diffuses inside the support and an alkali-soluble reaction is insufficient, a problem arises that residual layers are produced in an area which is supposed to be non-image areas, thus sensitivity becomes low, constituting an essential problem with an image recording layer of thermal positive type. In addition, a thermal positive type presensitized plate like this requires an infrared-ray absorbent having a photothermal converting function. Since the molecular weights of these absorbents are relatively large, their solubilities are low. In addition, these absorbents are difficult to be removed since they are attached to micro apertures (micropores) generated by anodizing treatment. Therefore, a problem arises that residual layers are easily produced in a development process with an alkali developer.

### SUMMARY OF THE INVENTION

It is an object of the present invention to provide a thermosensitive presensitized plate that overcomes the defects of the aforementioned related arts. That is, the object is to provide a thermosensitive presensitized plate that is capable of efficiently using heat for image formation, with high sensitivity, long press life when a lithographic printing plate is prepared, and high scum resistance in non-image areas.

The inventors have made intensive studies and as a result, found that the object described above can be achieved by combining an aluminum support having a specified grain shape and a hydrophilic layer having a specified thermal conductivity with a specified image recording layer. In other words, the inventors have found that a presensitized plate which comprises an aluminum support having a grain shape in a structure in which grained structures having specified average wavelength (average aperture diameters) are superimposed, a hydrophilic layer whose thermal conductivity falls within a predetermined range and which is formed on the aluminum support, and an image recording layer of thermal positive type formed on the hydrophilic layer, exhibits a high sensitivity, has a long press life when processed into a lithographic printing plate, and is resistant to scum in the non-image area.

The present invention has been completed on the basis of the finding described above.

That is, the present invention provides a presensitized plate comprising an aluminum support which has a grain shape in a structure in which a grained structure with large undulation of 2 to 30 μm average wavelength, a grained structure with medium undulation of 0.5 to 5 μm average aperture diameter and a grained structure with small undulation of 0.01 to 0.5 μm average aperture diameter are superimposed and in which an average ratio of depth to aperture diameter of the grained structure with small undulation whose average aperture diameter is 0.01 to 0.5 μm is 0.1 to 1.0; a hydrophilic layer whose thermal conductivity is 0.05 to 0.5 W/(m·K) and which is formed on the aluminum support; and an image recording layer which includes a water-insoluble and alkali-soluble resin and an infrared absorbent, in which solubility in an alkali aqueous solution is increased by heating, and which is formed on the hydrophilic layer.

The present invention also provides a presensitized plate comprising an aluminum support which has a grain shape in a structure in which a grained structure with large undulation of 2 to 30 μm average wavelength, a grained structure with medium undulation of 0.5 to 5 μm average aperture diameter and a grained structure with small undulation of 0.01 to 0.5 μm average aperture diameter are superimposed and in which an average ratio of depth to aperture diameter of the grained structure with small undulation whose average aperture diameter is 0.01 to 0.5 μm is 0.1 to 1.0; a hydrophilic layer which has a density ranging from 1.0 to 3.2 g/cm³ or a porosity ranging from 20 to 70% and which is formed on the aluminum support; and an image recording layer which includes a water-insoluble and alkali-soluble resin and an infrared absorbent, in which solubility in an alkali aqueous solution is increased by heating, and which is formed on the hydrophilic layer.

In a preferred embodiment, the grained structure with large undulation of 2 to 30 μm average wavelength, the grained structure with medium undulation of 0.5 to 5 μm average aperture diameter and the grained structure with small undulation of 0.01 to 0.5 μm average aperture diameter are superimposed to provide a triple structure.

In another preferred embodiment, the aluminum support is obtainable by subjecting an aluminum or aluminum alloy plate to mechanical graining treatment, chemical etching treatment in an alkali aqueous solution, desmutting treatment with an acid, electrochemical graining treatment using an electrolyte containing nitric acid, electrochemical graining treatment using an electrolyte containing hydrochloric acid, chemical etching treatment in an alkali aqueous solution and desmutting treatment with an acid in this order.

In still another preferred embodiment, the hydrophilic layer is an anodized layer formed by an anodizing treatment.

In the present invention, the hydrophilic layer is preferably subjected to a hydrophilic surface treatment with an aqueous solution of an alkali metal silicate.

Further, the amount of silicon atom adsorbed by the treatment with the alkali metal silicate is more preferably in the range of 0.1 to 15 mg/m².

In the present invention, it is also preferred that the image recording layer is of a superimposed structure which includes a lower layer formed on the hydrophilic layer lying on the support and an upper layer formed on the lower layer and that the lower layer or the upper layer, or both of them are made of a resin having an acid group.

In the present invention, it is also preferred that the presensitized plate is developed by a developer containing at least one compound selected from the group consisting of silicates and saccharides.

### BRIEF DESCRIPTION OF THE DRAWINGS

FIG. 1 is a waveform view showing an example of a trapezoidal wave used for electrochemical graining using an alternating current suitably used for the present invention.

FIG. 2 is a side view showing an example of a radial cell in electrochemical graining suitably used for the present invention.

FIG. 3 is a schematic view of a thermocomparator that can be used to measure the thermal conductivity in a layer thickness direction of the hydrophilic layer of a presensitized plate according to the present invention.

### DETAILED DESCRIPTION OF THE PREFERRED EMBODIMENTS

Hereafter, the present invention will be explained in detail.

[Aluminum Support]

<Aluminum Plate>

A metal substrate used for an aluminum support which is the support for a lithographic printing plate according to the present invention is an aluminum substrate. The aluminum plate used for an aluminum substrate_is made of a dimensionally stable aluminum-based metal, that is, aluminum or an aluminum alloy. Besides a pure aluminum plate, alloy with aluminum as the main component containing very small quantity of different elements, plastic film or paper laminated or vapor deposited with aluminum or aluminum alloy may be used. Further, as described in JP 48-18327 B, a composite sheet in which an aluminum sheet is combined on a polyethylene terephthalate film may be used.

While no particular limitation is placed, a pure aluminum plate is preferably used in the present invention. However, since it is difficult to produce perfectly pure aluminum from the viewpoint of refining technology, aluminum containing tiny quantity of different elements may be allowable. For example, well-known materials described in Aluminum Handbook 4-th edition (by Japan Light Metal Association, 1990), specifically, aluminum alloy plates such as JIS A1050, JIS A1100, JIS A3003, JIS A3005, International registered alloy 3103A and the like may be used as occasion arises. Also, an aluminum plate using aluminum alloy, a scrap aluminum material, or secondary bare metal having an aluminum (Al) content set to 99.4 to 95 wt %, and containing at least five selected from iron (Fe), silicon (Si), copper (Cu), magnesium (Mg), manganese (Mn), zinc (Zn), chrome (Cr), and titanium (Ti) in a later-described range may be used.

In the present invention, an aluminum plate having an Al content set to 95 to 99.4 wt %, which can reduce costs, may be used. If an Al content exceeds 99.4 wt %, allowable quantity of impurities is reduced, and thus the effect of reducing costs may be lowered. If an Al content is less than 95 wt %, quantity of impurities contained is large, causing inconveniences such as crack in rolling. More preferably, an Al content is 95 to 99 wt %, and 95 to 97 wt % is particularly preferable.

An Fe content is preferably 0.05 to 1.0 wt %. Fe is an element contained by around 0.1 to 0.2 wt % even in new bare metal, quantity of Fe dissolved in Al is small, and most remains as an intermetallic compound. If an Fe content exceeds 1.0 wt %, cracks easily occur in rolling, and if it is less than 0.05 wt %, the effect of reducing costs is reduced, which are not preferable. More preferably, an Fe content is 0.2 to 0.5 wt %.

An Si content is preferably 0.03 to 1.0 wt %. Si is an element greatly contained in scrap materials of JIS 2000, 4000 and 6000 series. Si is an element contained by about 0.03 to 0.1 wt % even in new bare metal, and present in a state of being dissolved in Al or as an intermetallic compound. When the aluminum plate is heated in the manufacturing process of a support, Si that has been dissolved may be deposited as elemental Si. It is known that elemental Si and an intermetallic compound of FeSi series adversely affect harsh ink scum resistance. Here, “harsh ink scum” means dotted or annular scum appearing on printed paper or the like as a result of easy adhering of ink to a surface of a non-image area of a lithographic printing plate when printing is carried out with many interruptions. If an Si content exceeds 1.0 wt %, for example, this may not be completely removed in later-described treatment using sulfuric acid (desmutting treatment). The Si content of less than 0.03 wt % leads to a cost increase because of the necessity for an ingot of high purity, which is not practical. The Si content is more preferably in the range of 0.04 to 0.15 wt %.

A Cu content is preferably 0.000 to 1.0 wt %. Cu is an element greatly contained in scraps of JIS 2000 and 4000 series. Cu is dissolved in Al relatively easily. If the Cu content exceeds 1.0 wt %, for example, desmutting treatment by a treatment with sulfuric acid is often impossible, whereupon the graining property is impaired. The Cu content is more preferably in the range of 0.000 to 0.1 wt % An Mg content is preferably 0.000 to 1.5 wt %. Mg is an element greatly contained in scraps of JIS 2000, 3000, 5000 and 7000 series materials. Especially, since it is much contained in a can end material, it is one of main impure metals contained in a scrap material. Mg is dissolved in Al relatively easily, and forms an intermetallic compound with Si. If the Mg content exceeds 1.5 wt %, for example, the strength of the aluminum plate may be too high.

An Mn content is preferably 0.000 to 1.5 wt %. Mn is an element greatly contained in scraps of JIS 3000 series materials. Especially, since it is much contained in a can body material, Mn is one of main impure metals contained in a scrap material. Mn is dissolved in Al relatively easily, and forms an intermetallic compound with Al, Fe and Si. If the Mn content exceeds 1.5 wt %, for example, the strength of the aluminum plate may be too high.

A Zn content is preferably 0.000 to 0.5 wt %. Zn is an element greatly contained especially in scraps of JIS 7000 series materials. Zn is dissolved in Al relatively easily. If the Zn content exceeds 0.5 wt %, for example, evenness in the grain shape on a surface obtained by graining treatments may be impaired.

A Ti content is preferably 0.003 to 0.5 wt %. Ti is an element normally added by 0.01 to 0.04 wt % as a crystal refinement material. Ti is an element contained relatively greatly in scraps of JIS 5000, 6000 and 7000 series materials. If the Ti content exceeds 0.5 wt %, for example, the surface having a grain shape may be etched and press life may deteriorate. The Ti content is more preferably in the range of 0.003 to 0.1 wt %.

The aluminum plate used in the present invention is produced by using the foregoing raw material cast by a common method, executing rolling and heat treatment as occasion arises, setting a thickness to, e.g., 0. 1 to 0.7 mm, and executing planarity correction when necessary. This thickness can be properly changed according to a size of a printing machine, a size of a printing plate or user's request.

With regard to a production method of the aluminum plate, for example, DC casting, a method omitting soaking and/or annealing from the DC casting method, and a continuous casting method can be used.

<Grain Shape on Surface>

The characteristic feature of the support for a lithographic printing plate according to the present invention is that the support has, on the surface thereof, a grain shape in a structure in which a grained structure with large undulation of 2 to 30 μm average wavelength, a grained structure with medium undulation of 0.5 to 5 μm average aperture diameter and a grained structure with small undulation of 0.01 to 0.5 μm average aperture diameter are superimposed.

The structure in which the grained structures having specified average wavelength (aperture diameters) are superimposed increases the surface area of a plate made of aluminum or an aluminum alloy, which enhances the adhesion between the plate and an anodized layer, an image recording layer or the like, and the press life.

According to the present invention, a grained structure with medium undulation of 0.5 to 5 μm average aperture diameter has functions of retaining an image recording layer mainly by anchoring effect so as to provide a long press life. If the average aperture diameter of a pit of the grained structure with medium undulation is less than 0.5 μm, press life of the lithographic printing plate may deteriorate due to decrease in contact characteristics with the image recording layer provided as an upper layer. On the other hand, if the average aperture diameter of the pit of the grained structure with medium undulation exceeds 5 μm, press life may deteriorate due to decrease in the number of pit boundary areas playing a role of the anchor.

The average aperture diameter of the pit of the grained structure with medium undulation is preferably 0.7 to 3 μm, more preferably 0.8 to 2 μm.

A grained structure with small undulation of 0.01 to 0.5 μm average aperture diameter superimposed on the aforementioned grained structure with medium undulation mainly plays a role of improving scum resistance. By combining the grained structure with small undulation with the grained structure with medium undulation, when fountain solution is supplied to the lithographic printing plate at the time of printing, a water film is evenly formed on the surface thereof, thereby generation of dirt in non-image areas being suppressed. If the average aperture diameter of the pit of the grained structure with small undulation is less than 0.01 μm, a good effect of water film formation may not be obtained. On the other hand, if the average aperture diameter of the pit of the grained structure with small undulation exceeds 0.5 μm, the aforementioned effect of improving press life by the grained structure with medium undulation may not be obtained since the grained structure with medium undulation is broken.

The average aperture diameter of the pit of the grained structure with small undulation is preferably 0.03 to 0.3 μm, more preferably 0.05 to 0.2 μm.

With regard to the grained structure with small undulation, scum resistance can be further improved by controlling not only the aperture diameter but also a depth of the pit. That is, it is preferable that the ratio of depth to aperture diameter of the grained structure with small undulation is 0.1 to 1.0. This reliably allows the evenly formed water film to be retained on the surface and scum resistance on the surface of the non-image areas is maintained for a long period.

The aforementioned structure in which a grained structure with medium undulation and a grained structure with small undulation are superimposed is further combined with a grained structure with large undulation of 2 to 30 μm average wavelength in a superimposed manner.

The grained structure with large undulation of 2 to 30 μm average wavelength has an effect of increasing an amount of water retained in the surface of the non-image areas of the lithographic printing plate. The more the water retained is in the surface, the less affected the surface of the non-image areas is by contamination in the atmosphere. This allows obtaining non-image areas that is not easily get dirty even though the printing plate is left as it stands during printing. In addition, if the grained structure with large-undulation is superimposed, it is easier to visually inspect an amount of fountain solution supplied to the surface of the printing plate at the time of printing. Namely, inspectability of the lithographic printing plate becomes excellent. If the average wavelength of the grained structure with large undulation is less than 2 μm, there may be no difference from the grained structure with medium undulation. If the average wavelength of the grained structure with large undulation exceeds 30 μm, inspectability of the printing plate may be impaired since the exposed non-image areas appear dazzling after exposure and development. The average wavelength of the grained structure with large undulation is preferably 4 to 15 μm, more preferably 6 to 12 μm.

In the support for a lithographic printing plate according to the present invention, following are methods of measuring the average aperture diameter of the grained structure with medium undulation on a surface, the average aperture diameter and the average depths with respect thereto of the grained structure with small undulation, and the average wavelength of the grained structure with large undulation.

(1) Average Aperture Diameter of a Grained Structure with Medium Undulation

The surface of a support is photographed at a magnification of 2,000 from right above with an electron microscope. Next, in an electron micrograph obtained, at least 50 pits of the grained structure with medium undulation (pit of medium undulation) in which circumferences of the pits are annularly connected are extracted, the aperture diameters are determined by reading the diameters of the pits, and an average aperture diameter is calculated.

In addition, in order to suppress dispersion among measurements, an equivalent circle diameter may be measured with commercial image analysis software. In this case, the aforementioned electron micrograph is digitized by being scanned with a scanner, and an equivalent circle diameter is found after it is converted into binary values with the software.

The measurement results by the inventors showed that a visual measurement and that of digitization were almost the same value. In the case of a structure in which the grained structure with large undulation are superimposed, a similar result was obtained.

(2) Average Aperture Diameter of a Grained Structure with Small Undulation

The surface of a support for a lithographic printing plate is photographed at a magnification of 50,000 from right above with a high resolution scanning electron microscope (SEM). In a SEM micrograph obtained, at least 50 pits of the grained structure with small undulation (pit of small undulation) are extracted, the aperture diameters are determined by reading the diameters of the pits and an average aperture diameter is calculated.

(3) Average of Ratio of Depth to Aperture Diameter of the Grained Structure with Small Undulation

The average of ratio of depth to aperture diameter of the grained structure with small undulation is obtained as follows. A broken-out section of a support is photographed at a magnification of 50,000 with a high resolution SEM. In a SEM micrograph obtained, at least 20 pits of small undulation are extracted, the ratios are obtained by reading the aperture diameters and depths, and an average ratio is calculated.

(4) Average Wavelength of a Grained Structure with Large Undulation

A scanning electron microscope, T-20 made by JEOL Ltd. was used to photograph the surface of a support at a magnification of 2,000. Thirty asperity components with large undulation are read in horizontal and vertical directions, respectively. The average value obtained is regarded as the average wavelength of a grained structure with large undulation.

<Surface Treatment>

The aluminum support of the present invention is obtained by subjecting the aluminum plate to a graining treatment and further forming a specific hydrophilic layer thereon. However, the method of preparing the aluminum support of the present invention may include various other steps than the graining treatment and the formation of the hydrophilic layer.

The aluminum plate is preferably processed into a support through the degreasing step for removing adhered rolling oil, desmutting treatment step for dissolving smut on the surface of the aluminum plate, graining treatment step for graining the surface thereof, anodizing treatment step for coating the surface of the aluminum plate with an anodized layer, hydrophilic surface treatment step for enhancing the hydrophilicity of the anodized layer, and the like.

The aluminum support of the present invention is preferably obtained by the preparation process including a graining treatment (electrochemical graining treatment) for subjecting the aluminum plate to an electrochemical graining treatment in an acid aqueous solution using an alternating current.

In addition to the electrochemical graining treatment, the method of preparing the aluminum support according to the present invention may also include an aluminum plate surface treatment step consisting of a combination of a mechanical graining treatment, a chemical etching treatment in an acid or alkali aqueous solution and the like. The graining treatment or other treatments for preparing the aluminum support according to the present invention may be performed by a continuous process or a batch process, but the continuous process is preferably used from an industrial point of view.

According to a preferred embodiment of the method for preparing the aluminum support in the present invention, an aluminum or aluminum alloy plate is subjected to mechanical graining treatment, chemical etching treatment in an alkali aqueous solution, desmutting treatment with an acid, electrochemical graining treatment using an electrolyte containing nitric acid, electrochemical graining treatment using an electrolyte containing hydrochloric acid, chemical etching treatment in an alkali aqueous solution and desmutting treatment with an acid in this order. When an aluminum or aluminum alloy plate is grained by this method, a structure in which a grained structure with large undulation, a grained structure with medium undulation and a grained structure with small undulation are superimposed is appropriately formed, whereupon press life and scum resistance are improved.

<Graining Treatment>

Graining treatment is first described below.

The aluminum plate is subjected to a graining treatment so as to have a more preferred shape.

The grain shape on the surface of a support for a lithographic printing plate must be in a structure in which grained structures having specified average wavelength (aperture diameters) are superimposed. The surface of a support for a lithographic printing plate has preferably a grooved grain shape in a structure in which a grained structure with large undulation of 2 to 30 μm average wavelength, a grained structure with medium undulation of 0.5 to 5 μm average aperture diameter and a grained structure with small undulation of 0.01 to 0.5 μm average aperture diameter are superimposed.

A method of forming a grain shape is described below.

As a graining treatment method, there are mechanical graining as described in JP 56-28893 A, chemical etching, electrolytic graining and the like. Furthermore, an electrochemical graining (electrolytic graining) method for graining a surface of aluminum in an electrolyte containing hydrochloric aid (hydrochloric acid electrolyte) or an electrolyte containing nitric aid (nitric acid electrolyte) electrochemically, a mechanical graining method such as a wire brushing graining method for scratching a surface of aluminum plate with metal wire, a ball graining method for graining a surface of aluminum plate with abrasives and a graining ball, a brush graining method for graining the surface with nylon brushes and abrasives, may be used. These graining methods may be used alone or in combination. For example, a combination of mechanical graining treatment with nylon brushes and abrasives with electrolytic graining treatment by hydrochloric acid electrolyte or nitric acid electrolyte, and a combination of multiple electrolytic graining treatments may be enumerated. Among these graining methods, electrochemical graining treatment is desirable. A preferable combination is mechanical graining treatment with electrochemical graining and, especially, the electrochemical graining treatment is preferably carried out after the mechanical graining treatment.

(Mechanical Graining Treatment)

The mechanical graining treatment mechanically grains the surface of the aluminum plate by using a brush or the like. Preferably, it is carried out before the electrochemical graining treatment.

In the preferable mechanical graining treatment, treatment is carried out by a rotatable nylon brush roll having a bristle diameter of 0.07 to 0.57 mm, and abrasive slurry liquid fed to the surface of the aluminum plate.

A nylon brush having a lower absorption factor is preferable. A preferred example is Nylon Bristle 200T by Toray Industries, Inc., (6, 10-nylon, softening point: 180° C., melting point: 212 to 214° C., specific gravity: 1.08 to 1.09, moisture percentage: 1.4 to 1.8 wt % in 20° C. and relative humidity 65%, and 2.2 to 2.8 wt % in 20° C. and relative humidity 100%, dry tensile strength: 4.5 to 6 g/d, dry tensile elongation: 20 to 35%, boiling water contraction percentage: 1 to 4 %, dry tensile resistance: 39 to 45 g/d, Young's modulus (dry): 380 to 440 kg/mm²).

Well-known abrasives can be used. Preferably, however, silica sand, quartz, aluminum hydroxide, or a mixture of these described in JP 6-135175 A and JP 50-40047 B is used.

For the slurry liquid, preferably, specific gravity is set in a range of 1.05 to 1.3. As a method of feeding the slurry liquid to the surface of the aluminum plate, for example, a method of spraying the slurry liquid, a method using a wire brush, and a method of transferring the surface shape of a roll having asperities to the aluminum plate may be enumerated. Besides, methods described in JP 55-74898 A, JP 61-162351 A, JP 63-104889 A may be used. Further, as described in JP 9-509108 A, a method can be used, which brush-polishes the surface of the aluminum plate in aqueous slurry containing a mixture of particles of alumina and quarts set in a range of 95:5 to 5:95 by weight. An average particle size of the mixture in this case is preferably set in a range of 10 to 80 μm, especially in a range of 15 to 60 μm.

In case of the brush graining method, the average depth of a recess formed by a long wavelength component (large undulation) on the surface of an aluminum support for a lithographic printing plate can be controlled by suitably selecting the conditions such as the mean grain diameter and maximum grain diameter of grains used as an abrasive, the hair diameter, density and thrust pressure of brush. It is preferable that the mean wavelength of a recess obtained by the brush graining method is 2 to 30 μm.

(Electrochemical Graining Treatment)

The electrochemical graining treatment electrochemically grains the surface of the aluminum plate by applying an alternating current in an acid aqueous solution while using the aluminum plate as an electrode, and it is different from the foregoing mechanical graining treatment.

According to the present invention, in the electrochemical graining treatment, the ratio Q_{C}/Q_{A} of the quantity of electricity when the aluminum plate becomes cathode, i.e., the quantity of electricity Q_{C} at the cathode side, to the quantity of electricity when it becomes anode, i.e., the quantity of electricity Q_{A} at the anode side, is set, for example in the range of 0.7 to 2.5. Thus, uniform honeycomb pits can be formed on the surface of the aluminum plate. If Q_{C}/Q_{A} is less than 0.7, honeycomb pits easily become non-uniform. The same also occurs when it exceeds 2.5. Preferably, Q_{C}/Q_{A} is set in a range of 0.7 to 1.5.

As a waveform of the alternating current used in the electrochemical graining treatment, a sine wave, a rectangular wave, a triangular wave, a trapezoidal wave and the like may be enumerated. Among them, the rectangular wave or the trapezoidal wave is preferable. As a frequency of the alternating current, 30 to 200 Hz is preferable from a viewpoint of costs for manufacturing a power supply device, more preferably 40 to 120 Hz.

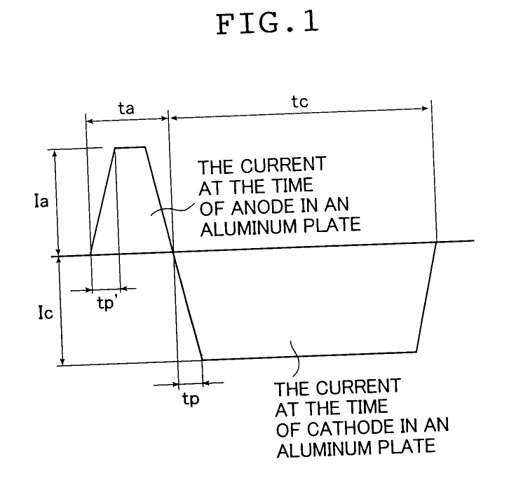

FIG. 1 shows an example of a trapezoidal wave suitably used in the present invention. An axis of ordinate indicates a current value, while an axis of abscissa indicates time. A reference numeral ta denotes anode reaction time, tc cathode reaction time, tp and tp′ each time for reaching a peak from a current value of 0, Ia a current at the peak time of the anode cycle side, and Ic a current at the peak time of the cathode cycle side. In the case of using the trapezoidal wave as the waveform of the alternating current, time tp and tp′ from the current values of 0 to reach the peaks are preferably 0.1 to 2 msec., and more preferably 0.3 to 1.5 msec., respectively. If tp and tp′ are less than 0.1 msec., impedance of a power supply circuit may be affected, necessitating a large power supply voltage at the rising time of a current waveform. Consequently, power supply device costs may be increased. If tp and tp′ exceed 2 msec., the effect of a very small quantity of component in acid aqueous solution becomes large, making the execution of uniform graining difficult.

Preferably, a duty of the alternating current used in the electrochemical graining is set in a range of 0.25 to 0.6 for the purpose of uniformly graining the surface of the aluminum plate, more preferably in a range of 0.3 to 0.5. The duty in the present invention is represented by ta/T when the time of continuing anode reaction of the aluminum plate (anode reaction time) is ta at a cycle T of the alternative current. Especially, on the surface of the aluminum plate during cathode reaction, dissolution or breaking of the oxide layer occurs in addition to the generation of smut components mainly containing aluminum hydroxide, becoming a starting point of pitting reaction at next anode reaction time of the aluminum plate. Thus, selection of the duty of the alternating current has a great effect on uniform graining.

Regarding a current density of the alternating current, in the case of the trapezoidal or rectangular wave, preferably, a current density Iap at the peak time of the anode cycle side, and a current density Icp at the peak time of the cathode cycle side are set to 10 to 200 A/dm². Preferably, Icp/Iap is set in a range of 0.9 to 1.5.

In the electrochemical graining treatment, a total of the quantity of electricity used for the anode reaction of the aluminum plate is preferably 50 to 1000 C/dm² when the electrochemical graining treatment is finished. Preferably, time of the electrochemical graining treatment is 1 sec., to 30 min.

Regarding the acid aqueous solution (electrolyte) used in the electrochemical graining treatment, what is used in general electrochemical graining treatment using a direct or alternating current can be used. Preferably, acid aqueous solution mainly containing nitric acid (nitric acid electrolyte) or acid aqueous solution mainly containing hydrochloric acid (hydrochloric acid electrolyte) is used.

Here, “mainly” means that a main component in the aqueous solution is contained by 30 wt % or more with respect to the entire components, preferably 50 wt %. The same applies to other components, hereafter.

For the acid aqueous solution mainly containing nitric acid, what is used in general electrochemical graining treatment using a direct or alternating current can be used. For example, one or more of nitric acid compounds such as aluminum nitrate, sodium nitrate, and ammonium nitrate can be used by being added to the nitric acid aqueous solution of nitric acid concentration 5 to 15 g/L at a concentration from 0.01 g/L to saturation. In the acid aqueous solution mainly containing nitric acid, metal contained in aluminum alloy, e.g., iron, copper, manganese, nickel, titanium, magnesium, silicon and the like, may be dissolved.

For the acid aqueous solution mainly containing nitric acid, preferably, one obtained by adding aluminum nitrate and ammonium nitrate to the nitric acid aqueous solution of nitric acid concentration 5 to 15 g/L is used such that nitric acid, ammonium salt and nitrate are contained, aluminum ions are set to 1 to 15 g/L, preferably 1 to 10 g/L, and ammonium ions are set to 10 to 300 ppm. The aluminum ions and the ammonium ions are naturally increased during the electrochemical graining treatment. In this case, preferably, a solution temperature is 10 to 95° C, more preferably 20 to 90° C., and particularly preferably 40 to 80° C.

For the acid aqueous solution mainly containing hydrochloric acid, what is used in general electrochemical graining treatment using a direct or alternating current can be used. For example, a solution where one or more of nitrates having nitrate ions such as aluminum nitrate, sodium nitrate and ammonium nitrate or hydrochlorides having chloride ions such as aluminum chloride, sodium chloride and ammonium chloride are added to an aqueous hydrochloric acid solution of 1 to 100 g/L at 1 g/L to saturation thereof can be used. In addition, a compound forming a complex with copper can be added at a rate of 1 to 200 g/L. In the acid aqueous solution mainly containing hydrochloric acid, metal contained in aluminum alloy, e.g., iron, copper, manganese, nickel, titanium, magnesium, silicon and the like, may be dissolved. 1 to 100 g/L of hypochlorous acid or hydrogen peroxide may be added.

It is particularly preferred that an aluminum salt (aluminum chloride) is added to an aqueous hydrochloric acid solution mainly containing 2 to 15 g/L of hydrochloric acid at a solution temperature of 15 to 50° C. so as to allow the concentration of an aluminum ion in the solution to be controlled in the range of 3 to 50 g/L. An additive to be added to an aqueous solution mainly containing hydrochloric acid, equipment, a power supply, a current intensity, a flow rate and a temperature which are used for a publicly known electrochemical graining treatment can be used.

The electrochemical graining treatment is performed after the mechanical graining treatment, so that the grain shape in the triple structure described above can be formed.

Moreover, the electrochemical graining treatment is performed several times, so that the grain shape in the triple structure in which the grained structures with large, medium and small undulations are superimposed can be formed.

The pits that have been formed improve scum resistance in non-image areas and press life of the printing plate. In the electrochemical graining, the quantity of electricity necessary for forming sufficient pits on the surface, i.e., a product of a current and time of feeding a current becomes an important condition. The capability of forming sufficient pits by a smaller quantity of electricity is preferable from a viewpoint of energy saving. Regarding surface roughness after the electrochemical graining treatment, preferably, arithmetic mean roughness (Rₐ) measured by a cutoff value of 0.8 mm, and an evaluation length of 3.0 mm in accordance with JIS B0601-1994 is set to 0.2 to 0.5 μm.

In the electrochemical graining treatment, a well-known electrolytic system of a vertical, flat or radial type can be used. Particularly, the radial electrolytic system described in JP 5-195300 A is preferable.

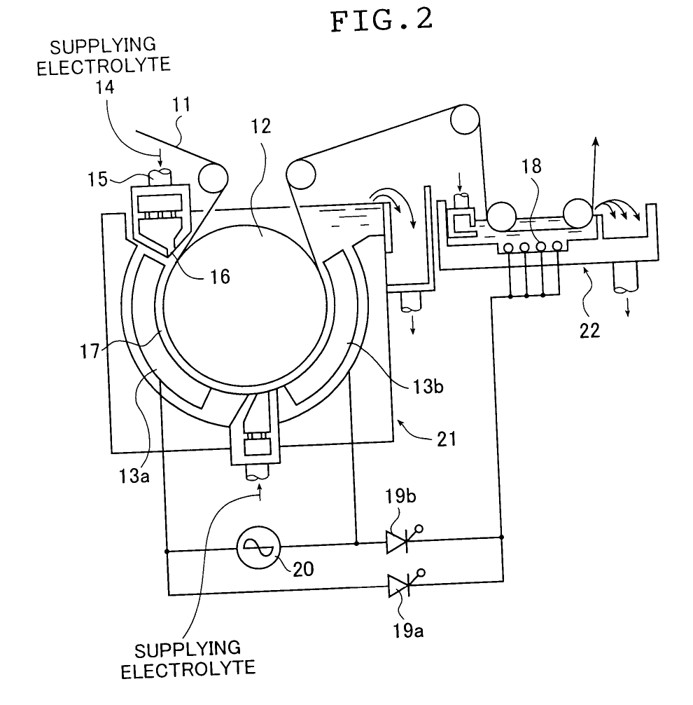

FIG. 2 is a schematic view of a radial electrolytic system suitably used for the present invention. In FIG. 2, 11 represents an aluminum plate, 12 represents a radial drum roller, 13a and 13b represent main poles, 14 represents an acid aqueous solution, 15 represents a solution feeding port, 16 represents a slit, 17 represents a solution passage, 18 represents an auxiliary anode, 19a and 19b represent thyristors, 20 represents an alternative power supply, 21 represents a main electrolytic cell, 22 represents an auxiliary anode cell. In FIG. 2, in the radial electrolytic system, the aluminum plate 11 is wound on the radial drum roller 12 disposed in the main electrolytic cell 21, and electrolysis is carried out by the main poles 13a and 13b connected to the alternative power supply 20 in the process of carrying. The acid aqueous solution 14 is fed from the solution feeding port 15 through the slit 16 to the solution passage 17 between the radial drum roller 12 and the main poles 13a and 13b.

Then, the aluminum plate 11 treated in the main electrolytic cell 21 is subjected to electrolysis in the auxiliary anode cell 22. This auxiliary anode cell 22 includes the auxiliary anode 18 disposed oppositely to the aluminum plate 11, and the acid aqueous solution 14 is fed to flow between the auxiliary anode 18 and the aluminum plate 11. A current supplied to the auxiliary electrode is controlled by the thyristors 19a and 19b.

The main poles 13a and 13b can be selected from carbon, platinum, titanium, niobium, zirconium, stainless, an electrode used for a fuel cell cathode and the like, and especially carbon is preferable. As carbon, commercially available impermeable graphite for a chemical device, resin-impregnated graphite or the like can be used.

The auxiliary anode 18 can be selected from well-known oxygen generating electrodes, such as ferrite, iridium oxide, platinum or one obtained by cladding or plating platinum on valve metal such as titanium, niobium, or zirconium.

The feeding direction of the acid aqueous solution passed in the main electrolytic cell 21 and the auxiliary anode cell 22 may be parallel to, or counter to the advancing direction of the aluminum plate 11. A relative flow velocity of the acid aqueous solution to the aluminum plate is preferably 10 to 1000 cm/sec.

One or more alternating current power supplies can be connected to one electrolytic system. Two or more electrolytic systems may be used, and electrolytic conditions may be similar or varied from system to system.

After the end of electrolysis, preferably, liquid removal by a nip roller, and water washing by a spray are carried out in order to prevent carrying of the treatment liquid to a next step.

In the case of using the foregoing electrolytic system, to maintain the concentration of the acid aqueous solution constant, preferably, the following method is used. For example, when components of the acid aqueous solution include nitric acid or hydrochloric acid and aluminum ion, for some sample solutions that have known nitric acid or hydrochloric acid and aluminum ion concentration, a propagation velocity of an ultrasonic wave and a conductivity of the acid aqueous solution, as physical quantity data, are measured at varied temperature beforehand. Each of physical quantity data and nitric acid or hydrochloric acid and aluminum ion concentration are compared. Depending on the result, demanded quantity of nitric acid or hydrochloric acid and aluminum ion are added, or water is added to dilute. Thus, the concentration of the acid aqueous solution is controlled.

Next, description is made of surface treatments including chemical etching treatment in acid aqueous solution (acid etching treatment) or alkali aqueous solution (alkali etching treatment), desmutting treatment, and the like in due order. The surface treatments are carried out before or after the electrochemical graining treatment, and before later-described anodizing treatment. However, the description of each surface treatment below is exemplification, and not limited to a content of each treatment. The following treatments including the foregoing surface treatments are optionally carried out.

(Alkali Etching Treatment)

Alkali etching treatment is a treatment of chemically etching the surface of the aluminum plate in alkali aqueous solution, and preferably carried out before and after the electrochemical graining treatment. If the mechanical graining treatment is carried out before the electrochemical graining treatment, preferably, the alkali etching treatment is carried out after the mechanical graining treatment. The alkali etching is more advantageous than later-described acid etching treatment, because it can destroy a micro-structure within a short time.

For alkali etching solution used in the alkali etching treatment, aqueous solution containing one or more selected from sodium hydroxide, sodium carbonate, sodium aluminate, sodium metasilicate, sodium phosphate, potassium hydroxide, and lithium hydroxide. Especially, aqueous solution mainly containing sodium hydroxide (caustic soda) is preferable. The alkali aqueous solution may contain 0.5 to 10 wt % of not only aluminum but also an alloy component contained in the aluminum plate.

Concentration of the alkali aqueous solution is preferably 1 to 50 wt %, more preferably 1 to 30 wt %.

The alkali etching treatment is preferably carried out at a liquid temperature of the alkali aqueous solution of 20 to 100° C., preferably 40 to 80° C., for 1 to 120 sec., preferably 2 to 60 sec. The dissolving quantity of aluminum is preferably 5 to 20 g/m² if it is carried out after the mechanical graining treatment, and is preferably 0.01 to 20 g/m² if it is carried out after the electrochemical graining treatment. If chemical etching solution is mixed in the alkali aqueous solution first, preferably the treatment solution is prepared by using liquid sodium hydroxide (caustic soda) and sodium aluminate (aluminate soda).

After the end of the alkali etching treatment, in order to prevent carrying of the treatment liquid to a next step, liquid removal by the nip roller and water washing by the spray are preferably carried out.

If the alkali etching treatment is carried out after the electrochemical graining treatment, smut generated by the electrochemical graining treatment can be removed. As such alkali etching treatment, for example, a method of bringing into contact with sulfuric acid of 15 to 65 wt % at a temperature of 50 to 90° C. described in JP 53-12739 A, and a method of alkali etching described in JP 48-28123 B can be suitably used.

In a grain shape having a triple structure in which a grained structure with large undulation, a grained structure with medium undulation and a grained structure with small undulation are superimposed, the wavelength value in large undulation, and the aperture diameter values in medium and small undulations can be controlled to a certain extent to fall within preferred ranges by the alkali etching described above.

(Acid Etching Treatment)

The acid etching treatment is a treatment for chemically etching the aluminum plate in acid aqueous solution, and preferably carried out after the electrochemical graining treatment. If the alkali etching treatment is carried out before and/or after the electrochemical graining treatment, preferably, the acid etching treatment is carried out after the alkali etching treatment.

By carrying out the acid etching treatment after the alkali etching treatment is executed on the aluminum plate, an intermetallic compound containing silica or elemental Si on the surface of the aluminum plate can be removed, and defects of an anodized layer formed in subsequent anodizing can be prevented. Therefore, it is possible to prevent a trouble of dotted ink adhered to non-image areas called chip-like scum during printing.

For the acid aqueous solution used in the acid etching treatment, aqueous solution containing phosphoric acid, nitric acid, sulfuric acid, chromic acid, hydrochloric acid, or mixed acid of two or more of these can be enumerated. Especially, sulfuric acid aqueous solution is preferable. Concentration of the acid aqueous solution is preferably 50 to 500 g/L. The acid aqueous solution may contain not only aluminum but also an alloy component contained in the aluminum plate.

The acid etching treatment is preferably carried out at a liquid temperature of 60 to 90° C., preferably 70 to 80° C., for 1 to 10 sec. The dissolving quantity of aluminum plate in this case is preferably 0.001 to 0.2 g/m². Acid concentration, for example, sulfuric acid concentration and aluminum ion concentration are preferably selected from a range causing no crystallization at a normal temperature. Preferable aluminum ion concentration is 0.1 to 50 g/L, more preferably 5 to 15 g/L.

After the end of the acid etching treatment, in order to prevent carrying of the treatment liquid to a next step, liquid removal by the nip roller and water washing by the spray are preferably carried out.

(Desmutting Treatment)

If the alkali etching treatment is carried out before and/or after the electrochemical graining treatment, smut is generally generated on the surface of the aluminum plate by the alkali etching treatment. Thus, preferably, so-called desmutting treatment is carried out after the alkali etching treatment, which dissolves the smut in acid solution containing phosphoric acid, nitric acid, sulfuric acid, chromic acid, hydrochloric acid, hydrofluoric acid, fluoroboric acid, or mixed acid of two kinds or more of these. After the alkali etching treatment, it is enough to carry out either one of the acid etching treatment or the desmutting treatment.

Concentration of the acid solution is preferably 1 to 500 g/L. In the acid solution, not only aluminum but also an alloy component contained in the aluminum plate may be dissolved by 0.001 to 50 g/L.

A liquid temperature of the acid solution is preferably 20 to 95° C., more preferably 30 to 70° C. Treatment time is preferably 1 to 120 sec., more preferably 2 to 60 sec.

For the desmutting treatment liquid (acid solution), use of waste liquid of the acid aqueous solution used in the foregoing electrochemical graining treatment is preferable for reducing the quantity of waste liquid.

After the end of the desmutting treatment, in order to prevent carrying of the treatment liquid to a next step, liquid removal by the nip roller and water washing by the spray are preferably carried out.

As a combination of the surface treatments, a preferable mode is as follows.

First, the mechanical graining treatment and/or alkali etching treatment is carried out, and then the desmutting treatment is carried out. Then, the electrochemical graining treatment is carried out several times, and subsequently any one of the following treatments is carried out: (1) acid etching treatment, (2) alkali etching treatment, and subsequent desmutting treatment, and (3) alkali etching treatment, and subsequent acid etching treatment.

A hydrophilic layer with a specified thermal conductivity is formed on the aluminum support according to the present invention, which is optionally followed by pore widening treatment (acid or alkali treatment), sealing treatment and hydrophilic surface treatment.

<Formation of the Hydrophilic Layer>

An aluminum plate on which graining treatment and, as required, other treatments are performed as mentioned above is provided with a hydrophilic layer with low thermal conductivity.

The thermal conductivity in the layer thickness direction of a hydrophilic layer is preferably 0.05 W/(m·K) or more, more preferably 0.08 W/(m·K) or more. The thermal conductivity in the layer thickness direction of a hydrophilic layer is preferably not more than 0.5 W/(m·K) more preferably not more than 0.3 W/(m·K) particularly preferably not more than 0.2 W/(m·K).

The diffusion of a heat generated by the exposure with a laser beam into a support can be suppressed by setting the thermal conductivity in the layer thickness direction of a hydrophilic layer at 0.05 to 0.5 W/(m·K). As a result, when used as a conventional thermal positive type, the presensitized plate according to the present invention exhibits a high sensitivity and has no problem of residual layer generation or unsatisfactory image formation.

Hereafter, the thermal conductivity in the layer thickness direction of a hydrophilic layer as specified in the present invention is described.

Various methods of measuring the thermal conductivity of a thin layer have been reported to date. In 1986, Ono et al. reported the thermal conductivity in the planar direction of a thin layer by use of a thermograph. In addition, there is also reported a trial that an alternating current heating method is applied to measure thermal properties of a thin layer. While the origin of alternating current heating method can trace back to a report in 1863, in recent years, various measurement methods have been proposed due to development of heating by laser and combinations with Fourier transform. Equipment with laser angstrom method is actually commercialized. Each of these methods finds the thermal conductivity of a planar direction (inplane direction).

However, a thermal diffusion in a depth direction is rather a vital factor when considering the thermal conduction of a thin layer. As variously reported, it is said that the thermal conductivity of a thin layer is not isotropic, and particularly in a case like the present invention, it is extremely important to directly measure the thermal conductivity in the layer thickness direction. As a trial to measure thermophysical properties in a layer thickness direction of a thin layer from the view point like this, a method using a thermocomparator is reported in a treatise published by Lambropoulos et al. (J. Appl. Phys., 66 (9)(Nov. 1, 1989)) and a treatise published by Henager et al. (APPLIED OPTICS, Vol. 32, No.1 (Jan. 1, 1993)). In addition, Hashimoto et al. recently reported a method of measuring thermal diffusivity of a thin polymer layer by an analysis using temperature wave for Fourier transform thermal analysis (Netsu Sokutei, 27 (3) (2000)).

The thermal conductivity in a layer thickness direction of a hydrophilic layer as defined in the present invention is measured with a method using the aforementioned thermocomparator. The method is concretely described below. The basic principle of the method is described in detail in the treatise published by Lambropoulos et al. and the treatise published by Henager et al. as aforementioned. In addition, equipment used for the method is not limited to the following equipment.

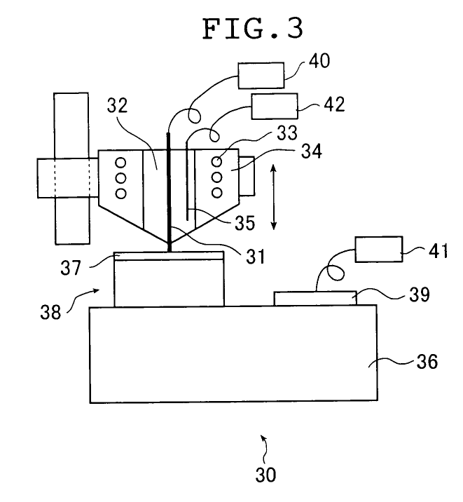

FIG. 3 is a schematic view of a thermocomparator 30 that can be used to measure the thermal conductivity in a layer thickness direction of the hydrophilic layer in a presensitized plate according to the present invention. As shown in FIG. 3, reference numeral 30 denotes a thermocomparator, reference numeral 31 denotes a chip, reference numeral 32 denotes a reservoir, reference numeral 33 denotes an electric heater, reference numeral 34 denotes a heating jacket, reference numeral 35 denotes a thermocouple, reference numeral 36 denotes a heat sink, reference numeral 37 denotes a layer, reference numeral 38 denotes a metal substrate, reference numeral 39 denotes a contact thermometer, reference numeral 40 denotes a chip tip thermograph, reference numeral 41 denotes a heat sink thermograph, and reference numeral 42 denotes a reservoir thermograph.

In a method using a thermocomparator, a measurement is largely affected by a contact area with a thin layer and the condition (i.e. roughness) of a contact surface. For that reason, it is essential that the tip of the thermocomparator 30 that contacts with the thin layer should be as fine as possible. For example, a chip (wire) 31 having a fine tip of radius r₁=0.2 mm made of oxygen-free copper is used.

This chip 31 is fixed in place at the center of the reservoir 32 made of constantan and the heating jacket 34 made of oxygen-free copper having the electric heater 33 is fixed in place around the reservoir 32. If this heating jacket 34 is heated by the electric heater 33 and the reservoir 32 is so controlled as to be at 60±1° C. while an output of the thermocouple 35 mounted inside the reservoir 32 is fed back, the chip 31 is heated to 60±1° C. On the other hand, the heat sink 36 made of oxygen-free copper of radius 10 cm and thickness 10 mm is prepared and the metal substrate 38 having the layer 37 to be measured is mounted on the heat sink 36. The surface temperature of the heat sink 36 is measured with the contact thermometer 39.

After the thermocomparator 30 is set up like this, a tip of the heated chip 31 is allowed to contact with the surface of the layer 37. The thermocomparator 30 is, for example, mounted at the tip of a dynamic microhardness meter in place of an indenter so as to be driven up and down, and is allowed to be pressed until the chip 31 hits the surface of the layer 37 and a 0.5 mN load is applied. This allows variation in a contact area between the layer 37 to be measured and the chip 31 to be minimized.

If the heated chip 31 is allowed to contact with the layer 37, the tip temperature of the chip 31 drops but reaches a stationary state at a specific constant temperature. This is because a heat quantity given to the chip 31 via the heating jacket 34 and the reservoir 32 from the electric heater 33 and a heat quantity diffused into the heat sink 36 via the metal substrate 38 from the chip 31 are equilibrated. In this case, the chip tip thermograph 40 records the tip temperature of the chip, the heat sink thermograph 41 records the temperature of the heat sink and the reservoir thermograph 42 records the temperature of the reservoir, respectively.

The relationship between each temperature as aforementioned and the thermal conductivity of the layer is described in the following equation [1]:

$$\frac{( {T}_{r} - {T}_{b} )}{( {T}_{r} - {T}_{t} )} = ( \frac{4 {K}_{1} {r}_{1}}{{K}_{t f} {A}_{3}} ) t + ( 1 + ( \frac{4 {K}_{1} {r}_{1}}{{K}_{2} {A}_{2}} ) {t}_{2} + ( \frac{ {K}_{1} {r}_{1}}{{K}_{4} {r}_{1}} ) ) \qquad [ 1 ]$$

Here, the symbols express the following:

Tₜ: Tip temperature of chip, T_{b}: Heat sink temperature, Tᵣ: Reservoir temperature, K_{tf}: Layer thermal conductivity, K₁: Thermal conductivity of reservoir, K₂: Thermal conductivity of chip (in case of oxygen-free copper, 400 W/(m·K)), K₄: Thermal conductivity of metal substrate (in case no layer is provided), r₁: Radius of curvature of tip of chip, A₂: Contact area between the reservoir and the chip, A₃: Contact area between the chip and the layer, t: Layer thickness, t₂: Contact thickness (≈0).

The gradient of the equation [1] is found by measuring each temperature (Tₜ, T_{b} and Tᵣ) while changing the layer thickness (t) and plotting them, and the thermal conductivity of a layer (K_{tf}) can be found. That is, as is clear from the equation [1], this gradient is a value that is determined by reservoir thermal conductivity (K₁), radius of curvature of tip of chip (r₁), layer thermal conductivity (K_{tf}) and contact area (A₃) between the chip and the layer. Since K₁, r₁ and A₃ are already known values, a value of K_{tf} can be found from the gradient.

The inventors have found thermal conductivity of an anodized layer (Al₂O₃) provided on an aluminum plate with the measuring method as above. The thermal conductivity of Al₂O₃ found from the gradient of the graph made from the results of measuring each temperature of the layer while changing the thickness thereof is 0.69 W/ (m·K). This well agrees with the results as described in the treatise published by Lambropoulos et al. as aforementioned. In addition, this result also indicates that the value of thermal property of the thin layer is different from that of bulk (thermal conductivity of bulk Al₂O₃ is 28 W/(m·K)).

It is preferable to use a method of measuring the thermal conductivity in a layer thickness direction of a hydrophilic layer in a presensitized plate according to the present invention, because a result without variation for even the surface on which graining is performed for a lithographic printing plate can be obtained by using a fine tip of a chip and keeping a pressing load constant. It is preferable that the value of a thermal conductivity is found as the average value of values measured at different several points, for example, at 5 points on a sample.

One of the preferred forms of the hydrophilic layer is either having the density of 1.0 to 3.2 g/cm³, or porosity of 20 to 70%.

A low-density layer is formed under the aforementioned conditions. The density of the formed layer can be found by, for example, the following equation from the weight measurement by Mason method (a method of measuring weight of an anodized layer by dissolving the layer in a mixture of chromic acid and phosphoric acid) and the thickness of the layer found by observing the cross section of the layer with SEM:

Density (g/m³)=(weight of layer per unit area/thickness of layer)

If the density of the formed layer is less than 1.0 g/m³, the strength of the layer may become weak, thereby badly affecting image forming characteristics and press life, and if the density exceeds 3.2 g/cm³, sufficient heat insulation can not be obtained, thereby decreasing a sensitivity-improving effect.

In the present invention, porosity of the hydrophilic layer should preferably be 20 to 70%, more preferably be 30 to 60%, and particularly preferably be 40 to 50%. If the porosity of the hydrophilic layer is 20% or more, thermal diffusion into an aluminum support is sufficiently suppressed and a sensitivity-improving effect can be sufficiently obtained. If the porosity of a hydrophilic layer is 70% or less, a problem that dirt is generated in non-image areas does not easily take place.

The porosity of the hydrophilic layer here means a volume ratio of an area of holes in the layer. In the case of an anodized layer, the porosity can be found from a pore diameter, depth, and number of pores obtained by SEM observation.

For example, a porosity of the hydrophilic layer is calculated by the following formula:

Porosity (%)=[1-(hydrophilic layer density/3.98)]×100

Here, the hydrophilic layer density (g/cm²) is obtained by [hydrophilic layer weight per unit area/hydrophilic layer thickness]. 3.98 means alumina density (g/cm²) according to Kagaku Binran (Chemical Manual).

By forming a hydrophilic layer having a density of 1.0 to 3.2 g/cm³, deterioration of the ink clean-up property or other problems associated with the scum generation during printing which may occur concomitantly with the increase of the sensitivity can be overcome.

The thickness of the hydrophilic layer should preferably be 0.1 μm or more from the view point of scratch resistance and press life, and more preferably be 0.3 μm or more, and particularly preferably be 0.6 μm or more. In addition, it should preferably be 5 μm or less, more preferably be 3 μm or less, and particularly preferably be 2 μm or less in terms of the manufacturing cost since a large energy is required to provide a thicker layer.

A method of providing the hydrophilic layer is not particularly limited, methods that can be used as appropriate include anodizing method, evaporation method, CVD method, sol-gel method, sputtering method, ion plating method, diffusion method and the like. In addition, a method by applying a solution in which hollow particles are mixed in a hydrophilic resin or a sol-gel liquid can be used.

Among those, a treatment for producing an oxide by an anodizing method, that is, an anodizing treatment is most preferably used. The anodizing treatment can be performed in the same method as in a method conventionally performed in this field of technology. Concretely, if direct current or alternating current is allowed to flow in an aluminum plate in an aqueous solution or a non-aqueous solution containing one or more kinds of sulfuric acid, phosphoric acid, chromic acid, oxalic acid, sulfamic acid, benzenesulfonic acid and the like,. an anodized layer that is a hydrophilic layer can be formed on the surface of an aluminum plate.

Although the conditions of anodizing treatment can not be indiscriminately determined since they are variously changed according to an electrolyte to be used, generally appropriate conditions are the concentration of an electrolyte: 1 to 80 wt %, the temperature of an electrolyte: 5 to 70° C., the current density: 0.5 to 60 A/dm², the voltage: 1 to 200 V and the time of electrolysis: 1 to 1000 seconds.

Among these anodizing treatments, the method of performing anodizing treatment at a high current density in a sulfuric acid electrolyte as described in GB 1,412,768 and the method of performing anodizing treatment in phosphoric acid as an electrolyte as described in U.S. Pat. No. 3,511,661 are preferable. In addition, a multi-stage anodizing treatment in which anodizing treatment is performed in sulfuric acid and subsequent anodizing treatment in phosphoric acid and the like may be performed.

In the present invention, the weight of an anodized layer should preferably be of 0.1 g/m² or more from the view point of scratch resistance and press life, more preferably be 0.3 g/m² or more, and particularly preferably 2 g/m² or more. In addition, since a large amount of energy is required to provide a thicker layer, it should preferably be 100 g/m² or less, more preferably be 10 g/m² or less, and particularly preferably be 6 g/m² or less.

Micro recesses called micropores are evenly formed on the surface of the anodized layer. The density of micropores existent in the anodized layer can be adjusted by selecting the treatment conditions appropriately. Thermal conductivity in the layer thickness direction of the anodized layer can be set at 0.05 to 0.5 W/(m·K) by increasing the density of a micropore.

In the present invention, it is preferable that after anodizing treatment is performed, pore widening treatment to widen the pore diameter of the micropore is performed to lower thermal conductivity. That is, this pore widening treatment dissolves the anodized layer to expand the pore diameter by dipping the aluminum plate on which the anodized layer is formed in an acid aqueous solution or an alkali aqueous solution. In performing pore widening treatment, a dissolved amount of the anodized layer should preferably be 0.01 to 20 g/m², more preferably be 0.1 to 5 g/m², and particularly preferably be 0.2 to 4 g/m².

When an acid aqueous solution is used for pore widening treatment, it is preferable that, inorganic acids such as sulfuric acid, phosphoric acid, nitric acid, hydrochloric acid or an aqueous solution of mixture of these are used. The concentration of the acid aqueous solution should preferably be 10 to 1,000 g/L, and more preferably be 20 to 500 g/L. The temperature of the acid aqueous solution should preferably be 10 to 90° C., and more preferably be 30 to 70° C. The time for dipping into the acid aqueous solution should preferably be 1 to 300 seconds, and more preferably be 2 to 100 seconds.

On the other hand, if an alkali aqueous solution is used for pore widening treatment, it is preferable that at least an alkali aqueous solution selected from a group consisting of sodium hydroxide, potassium hydroxide and lithium hydroxide is used. The pH of an alkali aqueous solution is preferably be 10 to 13, and more preferably be 11.5 to 13.0. The temperature of the alkali aqueous solution should preferably be 10 to 90° C., and more preferably be 30 to 50° C. The time for dipping into the alkali aqueous solution should preferably be 1 to 500 seconds, and more preferably to 2 to 100 seconds.

In addition to the aforementioned anodized layer, the hydrophilic layer may be an inorganic layer provided by sputtering method, CVD method or the like. The compounds constituting an inorganic layer may include oxide, nitride, silicate, borate and carbide. Further, the inorganic layer may be composed of either only a single compound or a mixture of compounds.

The compounds constituting an inorganic layer may concretely include aluminum oxide, silicon oxide, titanium oxide, zirconium oxide, hafnium oxide, vanadium oxide, niobium oxide, tantalum oxide, molybdenum oxide, tungsten oxide, chromium oxide; aluminum nitride, silicon nitride, titanium nitride, zirconium nitride, hafnium nitride, vanadium nitride, niobium nitride, tantalum nitride, molybdenum nitride, tungsten nitride, chromium nitride, silicon nitride, boron nitride; titanium silicide, zirconium silicide, hafnium silicide, vanadium silicide, niobium silicide, tantalum silicide, molybdenum silicide, tungsten silicide, chromium silicide; titanium boride, zirconium boride, hafnium boride, vanadium boride, niobium boride, tantalum boride, molybdenum boride, tungsten boride, chromium boride; aluminum carbide, silicon carbide, titanium carbide, zirconium carbide, hafnium carbide, vanadium carbide, niobium carbide, tantalum carbide, molybdenum carbide, tungsten carbide and chromium carbide.

<Sealing Treatment>

In the present invention, sealing treatment may be carried out for the aluminum support having the hydrophilic layer formed as described above.

For example, a sealing film is formed from a bottom of pores in the case of electrodeposition sealing treatment, and from an upper part of the pores in the case of steam sealing treatment. Thus, formation of a sealing film varies depending on the method of sealing treatment.

Sealing treatment suitably used in the present invention is a treatment for not sealing the inside of micropores, but only sealing upper part of the micropores.

As sealing treatment used in the present invention, sealing treatments of the hydrophilic layer by pressurized steam or hot water, described in JP 4-176690 A, and Japanese Patent Application No. 10-106819 (JP 11-301135 A) can be enumerated. Also, sealing treatment can be carried out by using well-known methods including treatment with silicate, treatment with bichromate aqueous solution, treatment with nitrite, treatment with ammonium acetate, electrodeposition sealing, treatment with triethanolamine, treatment with barium carbonate, treatment with hot water containing a very small amount of phosphate, and the like. Among others, sealing treatment suitably used in the present invention is a sealing treatment with fine particles described in Japanese Patent Application No. 2001-9871 (JP 2002-214764 A).

In the sealing treatment with fine particles, a particle layer containing particles having an average particle size of 8 to 800 nm, preferably 10 to 500 nm, more preferably 10 to 150 nm, is formed. A possibility of incursion of particles into micropores on the hydrophilic layer is small, and thus an effect of achieving a high sensitivity is provided. If an average particle size of particles is 800 nm or less, adhesion with a thermosensitive layer becomes sufficient, improving press life. A thickness of the particle layer is preferably 8 to 800 nm, more preferably 10 to 500 nm.

For the particles used in the present invention, a thermal conductivity is preferably 60 W/(m·K) or less, more preferably 40 W/(m·K) or less, particularly preferably 0.3 to 10 W/(m·K) or less. If a thermal conductivity is 60 W/(m·K) or less, suppression of heat diffusion to the aluminum support becomes sufficient, thereby providing a sufficient effect of achieving a high sensitivity.

No limitations are placed on methods of forming particle layers. However, a preferable example is a method, in which the aluminum support is subjected to electrolysis with direct current or alternating current by using electrolyte containing hydrophilic particles having an average particle size of 8 to 800 nm. For a waveform of the alternative current used in the electrolysis, a sine wave, a rectangular wave, a triangular wave, a trapezoidal wave may be enumerated. From a viewpoint of costs for manufacturing a power supply device, a frequency of the alternative current is preferably 30 to 200 Hz, more preferably 40 to 120 Hz. If the trapezoidal wave is used for the alternating current, time tp from a current 0 to a peak is preferably set to 0.1 to 2 msec., more preferably 0.3 to 1.5 msec. If the time tp is less than 0.1 msec., impedance of a power supply circuit may be affected, necessitating a large power supply voltage at the rising time of a current waveform. Thus, power supply device costs may be increased.

For hydrophilic particles, Al₂O₃, TiO₂, SiO₂, or ZrO₂ is preferably used singly, or a combination of two or more of these may be used. Electrolyte is obtained by slurrying the hydrophilic particles in water or the like such that content is 0.01 to 20 wt % of a total. The electrolyte can be adjusted in pH by, for example adding sulfuric acid or the like, in order to obtain plus or minus charges. The electrolysis is carried out, for example, by using a direct current and the electrolyte, with the aluminum support as a cathode, at a voltage of 10 to 200 V for 1 to 600 sec.

According to this method, it is possible to easily seal the openings of the micropores present on the hydrophilic layer while leaving voids inside.

Other than the foregoing sealing methods, dipping treatment in a liquid, spray treatment, deposition treatment, sputtering, ion plating, thermal spraying, gilding and the like can be enumerated. But no particular limitations are placed in this regard.

As specific treatment methods, methods of forming layers by coating, for example a layer made of a compound having at least one amino group, and at least one selected from the group consisting of a carboxy group, its salt group, a sulfo group and its salt group, described in JP 60-149491 A, a layer made of a compound having at least one amino group, and at least one hydroxy group and its salt, described in JP 60-232998 A, a layer containing phosphate, described in JP 62-19494 A, a layer made of a polymer compound containing at least one of monomer units having sulfo group as a repeated unit in a molecule, described in JP 59-101651 A, and the like.

Another example may be a method of forming a layer of a compound selected from carboxy-methyl cellulose; dextrin; gum Arabic; phosphonic acid having an amino group such as 2-aminoethylphosphonic acid; organic phosphonic acid such as phenylphosphonic acid, naphtylphosphonic acid, alkylphosphonic acid, glycerophosphonic acid, methylenediphosphonic acid, or ethylenediphosphonic acid, which may have a substituent; organic phosphoric acid ester such as phenylphosphoric acid, naphtylphosphoric acid, alkylphosphoric acid, or glycerophosphoric acid, which may have a substituent; organic phosphinic acid such as phenylphosphinic acid, naphtylphosphinic acid, alkylphosphinic acid, or glycerophosphinic acid, which may have a substituent; amino acid such as glycine or β-alanine; and amine hydrochloride having a hydroxy group such as triethanolamine hydrochloride.

In sealing treatment, silane coupling agents having unsaturated groups may be coated. Silane coupling agents may include, for example, N-3-(acryloxy-2-hydroxy propyl)-3-amino propyltriethoxy silane, (3-acryloxypropyl)-dimethylmethoxy silane, (3-acryloxypropyl)-methyldimethoxy silane, (3-acryloxypropyl)-trimethoxy silane, 3-(N-allylamino)-propyltrimethoxy silane, allyldimethoxy silane, allyltriethoxy silane, allyltrimethoxy silane, 3-butenyltriethoxy silane, 2-(chloromethyl)-allyltrimethoxy silane, methacrylamidepropyltriethoxy silane, N-(3-methacryloxy-2-hydroxypropyl)-3-aminopropyltriethoxy silane, (methacryloxymethyl)-dimethylethoxy silane, methacryloxymethyltriethoxy silane, methacryloxymethyltrimethoxy silane, methacryloxypropyldimethylethoxy silane, methacryloxypropyldimethylmethoxy silane, methacryloxypropylmethyldiethoxy silane, methacryloxypropylmethyldimethoxy silane, methacryloxypropylmethyltriethoxy silane, methacryloxypropylmethyltrimethoxy silane, methacryloxypropyltris(methoxyethoxy) silane, methoxydimethylvinyl silane, 1-methoxy-3-(tri-methylsiloxy)-butadiene, stylylethyltrimethoxy silane, 3-(N-stylylmethyl-2-aminoethylamino)-propyltrimethoxy silane hydrochloride, vinyldimethylethoxy silane, vinyldiphenylethoxy silane, vinylmethyldiethoxy silane, vinylmethyldimethoxy silane, O-(vinyloxyethyl)-N-(triethoxy silylpropyl) urethane, vinyltriethoxy silane, vinyltrimethoxy silane, vinyltri(t-butoxy) silane, vinyltriisopropoxy silane, vinyltriphenoxy silane, vinyltris(2-methoxyethoxy) silane, diallylaminopropylmethoxy silane. Among them, silane coupling agents having methacryloyl group or acryloyl group whose unsaturated group has high reactivity is preferable.

Other methods include sol-gel coating described in JP 5-50779 A, phosphonic acids coating descried in JP 5-246171 A, methods of coating backcoating materials described in JP 6-234284 A, JP 6-191173 A, and JP 6-230563 A, treatment with phosphonic acids described in JP 6-262872 A, coating described in JP 6-297875 A, a method of anodizing described in JP 10-109480 A, methods of dipping described in Japanese Patent Application No. 10-252078 (JP 2000-81704 A), and Japanese Patent Application No. 10-253411 (JP 2000-89466 A), and the like. Any one of these methods can be used.

<Surface Hydrophilic Treatment>

In the present invention, surface hydrophilic treatment may be performed on the aluminum support provided with the hydrophilic layer as described above by dipping the aluminum support in aqueous solution containing one or more kinds of hydrophilic compounds. As the hydrophilic compounds, examples include polyvinyl phosphonic acid, a compound containing a sulfonic acid group, a saccharide compound, and a silicate compound.

The compound having the sulfonic acid group contains aromatic sulfonic acid, its formaldehyde condensate, derivatives thereof, and salts thereof.

As the aromatic sulfonic acid, examples include phenolsulfonic acid, catecholsulfonic acid, resorcinolsulfonic acid, benzenesulfonic acid, toluenesulfonic acid, lignin sulfonic acid, naphthalenesulfonic acid, acenaphthene-5-sulfonic acid, phenanthrene-2-sulfonic acid, benzaldehyde-2(or 3)-sulfonic acid, benzaldehyde-2, 4(or 3,5)-disulfonic acid, oxybenzylsulfonic acids, sulfobenzoic acid, sulfanilic acid, naphthionic acid, and taurin. Among them, the benzenesulfonic acid, the naphthalenesulfonic acid, and ligninsulfonic acid are preferable. Formaldehyde condensates of the benzenesulfonic acid, the naphthalenesulfonic acid or the ligninsulfonic acid are preferable.

Further, these may be used as sulfonates. For example, sodium salt, potassium salt, lithium salt, calcium salt, and magnesium salt may be enumerated. Among them, the sodium salt and potassium salt are preferable.

Preferably, pH of the aqueous solution containing the compound having the sulfonic acid group is 4 to 6.5, and can be adjusted in the foregoing pH range by using sulfuric acid, sodium hydroxide, ammonia or the like.

The saccharide compound includes monosaccharides and its sugar alcohols, oligosaccharides, polysaccharides, and glycosides.

As the monosaccharide and its sugar alcohol, examples include triose such as glycerol and its sugar alcohol; tetrose such as threose or erythritol, and its sugar alcohol; pentose such as arabinose or arabitol, and its sugar alcohol; hexose such as glucose or sorbitol, and its sugar alcohol; heptose such as D-glycero-D-galactoheptose, or D-glycero-D-galactohepthitol, and its sugar alcohol; octose such as D-erythro-D-galactooctytol, and its sugar alcohol; nonose such as D-erythro-L-glyco-nonurose, and its sugar alcohol.

For the oligosaccharide, for example, disaccharide such as saccharose, trehalose, lactose and trisaccharide such as raffinose can be enumerated.

For the polysaccharide, for example, amylose, arabinan, cyclodextrin, cellulose alginate can be enumerated.

In the present invention, “glycoside” means a compound having a sugar part and a non-sugar part bonded through ether bond or the like.

The glycoside can be classified based on non-sugar parts. Examples include alkylglycoside, phenolglycoside, coumaringlycoside, oxycoumaringlycoside, flavonoidglycoside, anthraquinoneglycoside, triterpeneglycoside, steroidglycoside, and mustard oil glycoside.

As the sugar parts, the foregoing monosaccharide, and its sugar alcohol; oligosaccharide; and polysaccharide can be enumerated. Among them, the monosaccharide and the oligosaccharide are preferable, and the monosaccharide and the disaccharide are more preferable.

As an example of a preferable glycoside, compounds represented by the following formula (I) can be enumerated.

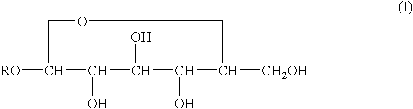

In the chemical formula (I), R represents alkyl group, alkenyl group or alkynyl group of the number of carbon atoms 1 to 20, being a straight chain or having a branched chain.

As the alkyl group of the number of carbon atoms 1 to 20, examples include methyl, ethyl, propyl, butyl, pentyl, hexyl, heptyl, octyl, nonyl, decyl, undecyl, dodecyl, tridecyl, tetradecyl, pentadecyl, hexadecyl, heptadecyl, octadecyl, nonadecyl and eicocyl groups, which may be a straight chain or a branched chain, or be cyclic alkyl groups.

As the alkenyl group of the number of carbon atoms 1 to 20, examples include allyl and 2-butenyl groups, which may be a straight chain or a branched chain, or be cyclic alkenyl groups.

As the alkynyl group of the number of carbon atoms 1 to 20, examples include 1-pentynyl group, which may be a straight chain or a branched chain, or be cyclic alkynyl groups.

Specific compounds represented by the foregoing formula (I) are, for example, methylglucoside, ethylglucoside, propylglucoside, isopropylglucoside, butylglucoside, isobutylglucoside, n-hexylglucoside, octylglucoside, caprylglucoside, decylglucoside, 2-ethylhexylglucoside, 2-pentylnonylglucoside, 2-hexyldecylglucoside, laurylglucoside, myristylglucoside, stearylglucoside, cyclohexylglucoside, and 2-butynylglucoside. These compounds are glucosides as one kind of glycoside, in which hemiacetalhydroxy group of glucose bonds other compounds in ether bond. For example, the compounds can be obtained by a well-known method of reacting glucose with alcohol. Parts of these alkylglucosides are commercially available as brand name GLUCOPON from Henkel Inc., of Germany, which can be used in the present invention.

Other examples of preferable glycosides include saponin, rutin trihydrate, hesperidin methyl chalcone, hesperidin, narijin hydrate, phenol-β-D-glucopyranoside, salicin, 3′,5,7-trimethoxy-7-rutinoside.

Preferably, pH of the aqueous solution containing the saccharide compound is 8 to 11, and can be adjusted in the foregoing pH range by using potassium hydroxide, sulfuric acid, carbonic acid, sodium carbonate, phosphoric acid, sodium phosphate or the like.

Concentration of the aqueous solution of the polyvinylphosphonic acid is preferably 0.1 to 5 wt %, more preferably 0.2 to 2.5%. A dipping temperature is preferably 10 to 70° C., more preferably 30 to 60° C. Dipping time is preferably 1 to 20 sec.

Concentration of the aqueous solution of the compound having the sulfonic acid group is preferably 0.02 to 0.2 wt %. A dipping temperature is preferably 60 to 100° C. Dipping time is preferably 1 sec. to 300 sec., more preferably 10 to 100 sec.

Further, concentration of the aqueous solution of the saccharide compound is preferably 0.5 to 10 wt %. A dipping temperature is preferably 40 to 70° C. Dipping time is preferably 2 to 300 sec., more preferably 5 to 30 sec.

In the present invention, in addition to the aqueous solutions of the organic compounds described above, aqueous solutions of inorganic compounds such as an aqueous solution of an alkali metal silicate, an aqueous solution of potassium zirconium fluoride (K₂ZrF₆), and an aqueous solution containing a phosphate/inorganic fluorine compound are advantageously used for the aqueous solution containing the hydrophilic compound.

Treatment with the aqueous solution of alkali metal silicate is carried out by dipping the support in the aqueous solution of alkali metal silicate having concentration of preferably 0.01 to 30 wt %, more preferably 0.1 to 10 wt %, in which pH at 25° C. is preferably 10 to 13, at a preferable dipping temperature of 10 to 100° C., more preferably 20 to 80° C., preferably for 0.5 to 40 sec., more preferably 1 to 20 sec.

Taken up as the alkali metal silicate used in the present invention for example are sodium silicate, potassium silicate, and lithium silicate. Among them, sodium silicate and potassium silicate are preferable.

In order to increase pH, the aqueous solution of the alkali metal silicate may contain hydroxides such as sodium hydroxide, potassium hydroxide, and lithium hydroxide by a proper quantity. Among them, sodium hydroxide, and potassium hydroxide are preferable.

Further, the aqueous solution of alkali metal silicate may contain alkaline-earth metal salt or the group 4 (IVB) metal salt. As the alkaline-earth metal salt, for example, water-soluble salts such as nitrate such as calcium nitrate, strontium nitrate, magnesium nitrate, or barium nitrate; sulfate; chloride; phosphate; acetate; oxalate; borate are enumerated. As the group 4 (IVB) metal salt, for example, titanium tetrachloride, titanium trichloride, titanium potassium fluoride, titanium potassium oxalate, titanium sulfate, titanium tetraiodide, zirconium chloride oxide, zirconium dioxide, zirconium oxychloride, zirconium tetrachloride are enumerated. Alkaline-earth metal salt and the group 4 (IVB) metal salt described above are used alone or in combination of 2 or more.

An amount of silicon adsorbed by alkali metal silicate treatment can be measured with a fluorescent X-ray analyzer, and its adsorbed amount should preferably be about 0.1 to 15.0 mg/m².

An effect to improve insolubility of the surface of an aluminum support for a lithographic printing plate with respect to an alkali developer can be obtained by performing this alkali metal silicate treatment. Further, since the elution of an aluminum component into the developer is suppressed, the generation of a development scum attributable to the exhaust of the developer can be reduced.

The treatment in the aqueous solution of the potassium zirconium fluoride is carried out by dipping the support in the aqueous solution of potassium zirconium fluoride at a preferable concentration of 0.1 to 10 wt %, more preferably 0.5 to 2 wt %, at a preferable temperature of 30 to 80° C., and preferably for 60 to 180 sec.

The treatment with the phosphate/inorganic fluorine compound is performed by dipping the support in an aqueous solution preferably at a pH of 3 to 5 having preferably a phosphate compound concentration of 5 to 20 wt % and an inorganic fluorine compound concentration of 0.01 to 1 wt %, preferably at 20 to 100 ° C., more preferably 40 to 80 ° C., preferably for 2 to 300 seconds, more preferably 5 to 30 seconds.

The phosphates used in the present invention include those of metals such as alkali metals and alkaline-earth metals.

Specific examples include zinc phosphate, aluminum phosphate, ammonium phosphate, diammonium hydrogenphosphate, ammonium dihydrogenphosphate, monoammonium phosphate, monopotassium phosphate, monosodium phosphate, potassium dihydrogenphosphate, dipotassium hydrogenphosphate, calcium phosphate, sodium ammonium phosphate, magnesium hydrogenphosphate, magnesium phosphate, ferrous phosphate, ferric phosphate, sodium dihydrogenphosphate, sodium phosphate, disodium hydrogenphosphate, lead phosphate, diammonium phosphate, calcium dihydrogenphosphate, lithium phosphate, phosphotungstic acid, ammonium phosphotungstate, sodium phosphotungstate, ammonium phosphomolybdate, sodium phosphomolybdate, sodium phosphite, sodium tripolyphosphate, and sodium pyrophosphate. Among these, sodium dihydrogenphosphate, disodium hydrogenphosphate, potassium dihydrogenphosphate, and dipotassium hydrogenphosphate are preferred.

As the inorganic fluorine compound used in the present invention, metal fluoride is preferable.

Specific examples include sodium fluoride, potassium fluoride, calcium fluoride, magnesium fluoride, sodium hexafluorozirconium, potassium hexafluorozirconium, sodium hexafluorotitanate, potassium hexafluorotitanate, hexafluorozirconium hydroacid, hexafluorotitanium hydroacid, ammonium hexafluorozirconium, ammonium hexafluorotitanate, hexafluorosilicic acid, nickel fluoride, iron fluoride, fluorophosphoric acid, ammonium fluorophosphate.

The aqueous solution used in the phosphate/inorganic fluorine compound treatment can contain one or more types of phosphates and inorganic fluorine compounds, respectively.

The support is dipped in the aqueous solution containing such hydrophilic compounds, then washed by water or the like and dried.

The sealing treatment or surface hydrophilic treatment solves the problem of print scum such as deterioration of scum resistance after being left (ink removing characteristic) caused in return for the increased sensitivity by the pore widening after the anodizing treatment. That is, because of the expanded pore diameter, during printing, especially the printing machine stops during printing and at the time of restarting of printing after the lithographic printing plate is left on the printing machine, ink removal becomes difficult. This phenomenon (deterioration of ink removing characteristic) easily occurs. However, the problem is reduced by performing the sealing treatment or the surface hydrophilic treatment.

<Undercoat Layer>

In the present invention, on the support for a lithographic printing plate thus obtained in the foregoing manner, before a recording layer, when necessary, for example an inorganic undercoat layer containing water soluble metallic salt such as zinc borate or an organic undercoat layer, may be provided.

As the organic compounds used for the organic undercoat layer, examples include carboxymethyl cellulose; dextrin; gum Arabic; polymer or copolymer having a sulfonic acid group at a side chain; polyacrylic acid; phosphonic acid having an amino group such as 2-aminoethyl phosphonic acid; organic phosphonic acid such as phenyl phosphonic acid, naphtyl phosphonic acid, alkyl phosphonic acid, glycero phosphonic acid, methylene diphosphonic acid, or ethylene diphosphonic acid, which may have a substituent; organic phosphoric acid such as phenyl phosphoric acid, naphtyl phosphoric acid, alkyl phosphoric acid, or glycero phosphoric acid, which may have a substituent; organic phosphinic acid such as phenyl phosphinic acid, naphtyl phosphinic acid, alkyl phosphinic acid, or glycero phosphinic acid, which may have a substituent; amino acid such as glycine or β-alanine; and amine hydrochloride having a hydroxy group such as triethanol amine hydrochloride; and yellow dye. These may be used alone, or in combination of 2 kinds or more.

The organic undercoat layer can be formed by the following methods. That is, those are a method of forming an organic undercoat layer by coating liquid obtained by dissolving the organic compound in water or organic solvent such as methanol, ethanol or methylethyl ketone, or mixed solvent thereof on the aluminum support, and drying it. Preferably, concentration of the solution containing the dissolved organic compound is 0.005 to 10 wt %. The coating method has no particular limitation, and any selected from bar coater coating, rotating coating, spray coating, and curtain coating and the like can be used.

The coating quantity of organic undercoat layer after dried is preferably 2 to 200 mg/M², more preferably 5 to 100 gm/M². In the above-described ranges, press life is improved more.

<Backcoat Layer>

On the support thus obtained in the foregoing manner, when processed into a presensitized plate, in order to prevent scratching of the recording layer if superposed, a covering layer (also referred to as “backcoat layer”, hereinafter) made of an organic polymer compound may be provided on a backside (surface of a side having no recording layer formed) when necessary.

Preferably, a main component of the backcoat layer is at least one resin selected from a group consisting of saturated copolymer polyester resin, a phenoxy resin, a polyvinyl acetal resin, and a vinylidene chloride copolymer resin, having a glass transition point of 20° C. or higher.

The saturated copolymer polyester resin includes a dicarboxylic acid unit, and a diol unit. As the dicarboxylic acid unit, examples include aromatic dicarboxylic acid such as phthalic acid, terephthalic acid, isophthalic acid, tetrabromophthalic acid, or tetrachlorophthalic acid; saturated aliphatic dicarboxylic acid such as adipic acid, azelaic acid, succinic acid, oxalic acid, suberic acid, sebatic acid, malonic acid, or 1, 4-cyclohexane dicarboxylic acid.

The backcoat layer can contain dye or pigment for coloring, silane coupling agent for improving adhesion with the support, diazo resin containing diazonium salt, organic phosphonic acid, organic phosphoric acid, cationic polymer, wax conventionally used as smoothing agent, higher fatty acid, higher fatty acid amide, a silicone compound made of dimethyl siloxane, modified dimethyl siloxane, polyethylene powder, and the like as occasion arises.

A thickness of the backcoat layer is basically set to a level for making it difficult for the recording layer to be scratched, described later, even if an interleaving sheet is not used, preferably 0.01 to 8 μm. If a thickness is less than 0.01 μm, it is difficult to prevent rubbing scratching of the recording layer when the presensitized plate is treated by being superposed. If a thickness exceeds 8μm, during printing, the backcoat layer is swelled by chemicals used around the lithographic printing plate, causing fluctuation in thickness. A printing pressure is thus changed to deteriorate a printing characteristic.

As the method of providing the backcoat layer on the backside of the support, various methods can be used. Examples include a method of dissolving a component for the backcoat layer in proper solvent to prepare solution, coating it, or dispersing to prepare emulsified liquid, coating it, and drying it; a method of bonding the backcoat layer formed in a film shape beforehand to the support by adhesive, heat or the like; and a method of forming a fused film by a fusion extruder, and bonding the film to the support. To secure a suitable thickness, the method of dissolving the component for the backcoat layer in proper solvent to prepare solution, coating the solution and drying it is most preferable. In this method, organic solvent described in JP 62-251739 A can be used alone, or in combination, as the solvent.

In production of the presensitized plate, any of the backcoat layer on the backside and the recording layer on the surface may be provided first, or both may be provided simultaneously.

[Presensitized Plate]

The presensitized plate of the present invention is prepared by forming on the aluminum support obtained as described above, an image recording layer which comprises a water-insoluble and alkali-soluble resin and an infrared absorbent and in which the solubility in an alkali aqueous solution is increased by heating.

<Image Recording Layer>

The image recording layer (thermosensitive layer) used in the presensitized plate of the present invention is a thermosensitive layer which comprises a water-insoluble and alkali-soluble resin and an infrared absorbent and in which the solubility in an alkali aqueous solution is increased by heating. A thermosensitive layer of a two or multi-layer construction is preferably used. Since an alkali-soluble layer and a dissolution-resistant surface layer can be provided separately, a larger discrimination can be obtained. Preferred examples of the thermosensitive layer of two or multi-layer construction are a thermosensitive layer having an easily alkali-soluble intermediate layer and a photosensitive layer rendered alkali-soluble by heating sequentially formed therein, and a thermosensitive layer of a superimposed structure provided apart from the intermediate layer. The easily alkali-soluble intermediate layer and the thermosensitive layer rendered alkali-soluble by heating are described below. Note that in the presensitized plate of the present invention, the image recording layer may be of a two-layer construction in which the “intermediate layer” and the “thermosensitive layer” to be mentioned below are provided, or of a one-layer construction in which the solubility in alkali on the aluminum support side is higher than that on the surface side.

The thermosensitive layer comprises an alkali-soluble resin (an alkali-soluble high-molecular compound) and an infrared ray absorptive dye (a photothermal conversion agent).

In the thermosensitive layer, the photothermal conversion agent converts the exposure energy of infrared laser and the like into heat, which efficiently cancels an interaction lowering the alkali-solubility of an alkali-soluble high-molecular compound.

Taken up as alkali-soluble high-molecular compound for example are a resin containing an acid group in a molecule and a mixture of two kinds or more of the resins. Particularly preferred is a resin having acid groups such as a phenolic hydroxy group, sulfonamide group (—SO₂ NH—R (where, R represents a hydrocarbon group)), and active imino group (—SO₂ NHCOR, —SO₂ NHSO₂ R or —CONHSO₂R (where, R has the similar meaning to the above.)) from the view point of the solubility of the resin in an alkali developer.

Above all, the resin having the phenolic hydroxy group is preferable since it is excellent in image-forming capability in the exposure by an infrared laser or the like. For example, novolac resins such as phenol-formaldehyde resin, m-cresol-formaldehyde resin, p-cresol-formaldehyde resin, m-/p-mixed cresol-formaldehyde resin and phenol/cresol (any of m-, p- and m-/p- mixed may be allowed) -mixed-formaldehyde resin (phenolcresolformaldehyde co-condensation resin), are preferably cited.

More specifically, polymers described in JP 2001-305722 A (particularly, [0023] to [0042]), polymers containing a repeating unit expressed by a general formula (1) as described in JP 2001-215693 A and polymers as described in JP 2002-311570 A (particularly, [0107]) are preferably used.

As the photothermal conversion agent, from a viewpoint of a recording sensitivity, pigment or dye, which has a light absorbing band in the infrared band ranging from 700 to 1200 nm in wavelength, is preferable. Concretely cited as the dye are azo dye, azo dye in the form of metallic complex salt, pyrazolone azo dye, naphthoquinone dye, anthraquinone dye, phthalocyanine dye, carbonium dye, quinonimine dye, methine dye, cyanine dye, squarylium dyestuff, pyrylium salt, metal thiolate complex (for example, nickel thiolate complex) and the like. Particularly, the cyanine dye is preferable and, for example, the cyanine dye represented by the general formula (I) in JP 2001-305722 A is cited.

A dissolution inhibitor can be contained in the thermosensitive layer. Suitably taken up as a dissolution inhibitor is one as described in [0053] to [0055] of JP 2001-305722 A.

In addition, it is preferred that a sensitivity regulator, a printing agent to obtain an visible image just after heated by exposure, compounds such as dyes as colorant, and a surfactant to improve coating property and treatment stability are contained in the thermosensitive layer as additives. Compounds as described in [0056] to [0060] of JP 2001-305722 A are preferred for these compounds.

Besides the foregoing aspects, suitably used are photosensitive compositions as described in 2001-305722 A.

In addition, the thermosensitive layer may be of a single layer structure or of a two-layer structure as described in JP 11-218914 A.

Suitably taken up as the thermosensitive layer of a two-layer structure (thermosennsitive layer of superimposed-type) is a type where a lower layer (hereinafter referred to as “A layer”) excellent in press life and solvent resistance is provided on the side closer to the support and a layer (hereinafter referred to as “B layer”) excellent in an image-forming capability of positive type is provided on the A layer. This type is of high sensitivity and can realize a broader development latitude. The B layer generally contains a photothermal conversion agent. The above-mentioned dyes are suitably taken up as photothermal conversion agents.

Suitably taken up as resins used for the A layer is a polymer which includes a monomer having sulfonamide group, active imino group, phenolic hydroxy group and the like as a copolymerization component since the polymer is excellent in press life and solvent resistance. Suitably taken up as resins used for the B layer is a resin soluble in an alkali aqueous solution having a phenolic hydroxy group.

Various additives can be contained in compositions used for the A and B layers as required besides the aforementioned resins. Concretely, suitably used are various additives as described in [0062] to [0085] of JP 2002-323769 A. In addition, also suitably used are additives as described in [0053] to [0060] of JP 2001-305722 A as aforementioned.

It is preferred that for each component and its content included in the A layer or the B layer, what is described in JP 11-218914 A is followed.

<Intermediate Layer>

It is preferred that an intermediate layer is provided between the thermosensitive layer and the support. Suitably taken up as components contained in the intermediate layer are various organic compounds as described in [0068] of JP 2001-305722 A.

<Others>

As a method for preparing the thermosensitive layer and a method for making a plate, can be used a method as described in detail in JP 2001-305722 A.

<Application Method>

A fluid for forming the image recording layer is applied to the grained surface of the support for a lithographic printing plate described above by conventionally known methods including a method using a coating rod, a method using an extrusion type coater, and a method using a slide bead coater. The application method can be implemented under conventionally known conditions.

As the device for drying an aluminum plate to which the fluid for forming the image recording layer has been applied, can be used an arch type drier in which the aluminum plate is dried while being transported by path rolls provided therein, an air dryer in which air is supplied from nozzles located on the upper and lower sides thereof to dry a web while it is floated, a radiant heat dryer in which radiant heat from a medium heated at a high temperature is used for drying, and a roller dryer in which heat transmission through contact with heated rollers is used for drying, as described in JP 6-63487 A.

[Lithographic Printing Plate]

The presensitized plate of the present invention is made into a lithographic printing plate by various treatment methods in accordance with the kind of the image recording layer.

In general, image exposure is carried out. Cited as light sources of active rays for use in the image exposure are, for example, a mercury lamp, a metal halide lamp, a xenon lamp and a chemical lamp. As laser beams, for example, helium-neon (He—Ne) laser, argon laser, krypton laser, helium-cadmium laser, KrF excimer laser, semiconductor laser, YAG laser and YAG-SHG laser are cited.

It is preferable that the presensitized plate is developed by use of a developer after the exposure to obtain the lithographic printing plate. Although a preferable developer for use in the presensitized plate of the present invention is not particularly limited as long as the developer is an alkali developer, an alkali aqueous solution that does not substantially contain an organic solvent is preferable. Moreover, the development can be carried out by use of a developer that does not substantially contain alkali metal silicate. The developing method using the developer that does not substantially contain the alkali metal silicate is described in detail in JP 11-109637 A, and the contents described in JP 11-109637 A can be used. Moreover, the presensitized plate of the present invention can be developed by use of a developer that contains the alkali metal silicate.

### EXAMPLES

Next, specific examples of the present invention will be described, but these are not restrictive of the present invention.

### Examples 1-9 and Comparative Examples 1-5

1. Preparation of a Support for a Lithographic Printing Plate (Aluminum Support).

<Aluminum Plate>

Molten metal was prepared by using an aluminum alloy containing Si: 0.06 wt %, Fe: 0.30 wt %, Cu: 0.001 wt %, Mn: 0.001 wt %, Mg: 0.001 wt %, Zn: 0.001 wt % and Ti: 0.03 wt %, and containing Al and inevitable impurities for the remaining portion. After molten metal treatment and filtering were performed, an ingot having a thickness of 500 mm and a width of 1200 mm was made by a DC casting method. After the surface was chopped to have an average thickness of 10 mm with a surface chipper, the ingot was held at 550° C. for about 5 hours for soaking. When the temperature dropped to 400° C., the ingot was formed into a rolled plate having a thickness of 2.7 mm by using a hot rolling mill. Further, after the heat treatment was performed at 500° C. with a continuous annealing machine, the roller plate was finished into an aluminum plate having a thickness of 0.24 mm with cold rolling to obtain an aluminum plate of JIS 1050 material. This aluminum plate was processed to have a width of 1030 mm.

The thus obtained aluminum plate is sequentially subjected to the methods for graining treatment and those for providing a hydrophilic layer to be described below by various combinations shown in Table 1 to thereby yield aluminum supports in Examples 1 to 9 and Comparative Examples 1 to 5.

TABLE 1

| | | Method of |
|---|---|---|
| | Method of | providing |
| | graining | a hydrophilic |
| | treatment | layer |
| Example 1 | A | a |
| Example 2 | B | a |
| Example 3 | C | a |
| Example 4 | D | a |
| Example 5 | E | a |
| Example 6 | F | a |
| Example 7 | G | a |
| Example 8 | A | b |
| Example 9 | A | c |
| Comparative | A | d |
| Example 1 | | |
| Comparative | A | e |
| Example 2 | | |
| Comparative | H | a |
| Example 3 | | |
| Comparative | I | a |
| Example 4 | | |
| Comparative | J | a |
| Example 5 | | |

<Graining Treatment>

(Method of Graining Treatment A)

Various surface treatments of (1) to (9) mentioned below were continuously performed. Furthermore, a liquid squeezing was performed by a nip roller after each treatment and water washing.

(1) Mechanical Graining Treatment

Mechanical graining treatment was carried out by brush roller having rotating nylon brushes while supplying suspension containing abrasive (pumice, average particle diameter:25 μm) and water having specific gravity of 1.1 g/cm³ as abrasive slurry liquid to the surface of the aluminum plate through a spray pipe.

A material for the nylon brush was 6,10-nylon, having a bristle length of 50 mm, and a bristle diameter of 0.30 mm. The nylon brush was made by boring holes in a φ300 mm stainless cylinder and densely implanting bristles therein. Three of such nylon brushes were placed to the brush roller. Each distance between two supporting rollers (φ200 mm) provided in the lower part of the brush was 300 mm.

The brush roller was pressed against the aluminum plate such that a load of the driving motor for rotating the brush was controlled with respect to a load before the nylon brush was pressed against the aluminum plate, and arithmetical mean roughness (Rₐ) of the aluminum plate after graining reached 0.45 μm. The direction in which the brush was rotated was the same as the direction in which the aluminum plate was moved. Then, washing was carried out.

Concentration of the abrasive was calculated from a temperature and a specific gravity by referring to a table made beforehand based on a relation among concentration, a temperature and a specific gravity. Water and the abrasive were added by feedback control, and the concentration of the abrasive was maintained constant. When the abrasive is crushed to reduce the particle sizes, the surface shape of the grained aluminum plate is changed. Thus, abrasives having small particle sizes were discharged out of the system by a cyclone each time. A particle size of the abrasive was in a range of 1 to 100 μm.

(2) Alkali Etching Treatment

The aluminum plate was subjected to alkali etching treatment by spraying aqueous solution containing 27 wt % of NaOH and 6.5 wt % of aluminum ions at a liquid temperature of 70° C. to the aluminum plate. A surface of the aluminum plate to be subjected to electrochemical graining treatment later was dissolved by 10 g/m², and a backside was dissolved by 2 g/m².

Concentration of etching solution used in the alkali etching treatment was calculated based on a temperature, specific gravity and an electric conductivity by referring to a table made beforehand based on a relation among NaOH concentration, aluminum ion concentration, a temperature, specific gravity and liquid electric conductivity, and maintained constant by adding water and 48 wt % of NaOH aqueous solution based on feedback control. Then, washing was carried out.

(3) Desmutting Treatment

The aluminum plate was subjected to spray desmutting treatment with aqueous solution of nitric acid at a liquid temperature of 35° C. for 10 sec. For the aqueous solution of nitric acid, waste solution overflown from an electrolysis device used in the next step was used. Then, spray pipes for spraying desmutting treatment solution were installed in a plurality of places, and thus drying of the surface of the aluminum plate was prevented until a next step.

(4) Electrochemical Graining Treatment

Electrochemical graining treatment was continuously carried out by using an alternative current of a trapezoidal wave shown in FIG. 1, and two electrolytic cells shown in FIG. 2. Acid aqueous solution in this case was the aqueous solution of nitric-acid 9.5 g/L (containing aluminum ions 5.0 g/L, and ammonium ions 0.07 g/L), and the liquid temperature was 50° C. For the alternating current, the conditions were set as follows, that is, a time period tp in which a current value goes up from 0 to a peak at cathode cycle side and a time period tp′ in which a current value goes up from 0 to a peak at anode cycle side were 0.8 msec., respectively, and carbon electrodes were set as counter electrodes. Current densities at the peak of the alternating current were 50 A/dm² at both times when the aluminum plate was at the anode and at the cathode side, a duty ratio was 0.50, a frequency was 60 Hz, and the total quantity of electricity at the anode side was 160 C/dm². Then, washing was carried out by spraying.

Concentration control of the aqueous solution of nitric acid was carried out by adding nitric acid stock solution of 67 wt % and water in proportion to the quantity of supplied electricity, overflowing acid aqueous solution (aqueous solution of nitric acid) equal in quantity to the added volume of nitric acid and water from the electrolysis device each time, and discharging it out of the electrolysis device. Also, concentration of the aqueous solution of nitric acid was calculated based on a temperature, an electric conductivity and an ultrasonic wave propagation speed of the nitric acid aqueous solution by referring to a table made beforehand based on a relation among nitric acid concentration, aluminum ion concentration, a temperature, a liquid electric conductivity and a liquid ultrasonic wave propagation speed. Then, the concentration was maintained constant by performing control to adjust the added quantity of the nitric acid stock solution and water successively.

(5) Alkali Etching Treatment

The aluminum plate was subjected to alkali etching treatment by spraying aqueous solution containing 26 wt % of NaOH and 6.5 wt % of aluminum ions at a liquid temperature of 45° C. to the aluminum plate. The aluminum plate was dissolved by 1.0 g/m². Concentration of etching solution was calculated based on a temperature, specific gravity and an electric conductivity by referring to a table made beforehand based on a relation among NaOH concentration, aluminum ion concentration, a temperature, specific gravity and liquid electric conductivity, and maintained constant by adding water and 48 wt % of NaOH aqueous solution based on feedback control. Then, washing was carried out.

(6) Acid Etching Treatment

The aluminum plate was subjected to acid etching treatment by using sulfuric acid (sulfuric acid concentration 300 g/L, and aluminum ion concentration 15 g/L) as an acid etching solution, and spraying this to the aluminum plate from a spray pipe at a temperature of 80° C. for 8 sec. Concentration of the acid etching solution was calculated based on a temperature, specific gravity and an electric conductivity by referring to a table made beforehand based on a relation among sulfuric acid concentration, aluminum ion concentration, a temperature, specific gravity and liquid electric conductivity, and maintained constant by adding water and 50 wt % of sulfuric acid aqueous solution based on feedback control. Then, washing was carried out.

(7) Electrochemical Graining Treatment

Electrochemical graining treatment was continuously carried out by using an alternative current of a trapezoidal wave shown in FIG. 1, and two electrolytic cells shown in FIG. 2. Acid aqueous solution in this case was the aqueous solution of hydrochloric acid of 5.0 g/L (containing aluminum ions 4.5 g/L), and the liquid temperature was 35° C. For the alternating current, the conditions were set as follows, that is, a time period tp in which a current value goes up from 0 to a peak at cathode cycle side and a time period tp′ in which a current value goes up from 0 to a peak at anode cycle side were 1 msec., respectively, and carbon electrodes were set as counter electrodes. Current densities at the peak of the alternating current were 25 A/dm² at both times when the aluminum plate was at the anode and at the cathode side, a ratio (Q_{C}/Q_{A}) of the quantities of electricity of the alternating current at cathode time (Q_{C}) to at anode time (Q_{A}) was 0.95, a duty ratio was 0.50, a frequency was 60 Hz, and the total quantity of electricity at the anode side was 50 C/dm². Then, washing was carried out by spraying.

Concentration control of the aqueous solution of hydrochloric acid was carried out by adding hydrochloric acid stock solution of 30 wt % and water in proportion to the quantity of supplied electricity, overflowing acid aqueous solution (aqueous solution of hydrochloric acid) equal in quantity to the added volume of hydrochloric acid and water from the electrolysis device each time, and discharging it out of the electrolysis device. Also, concentration of the aqueous solution of hydrochloric acid was calculated based on a temperature, an electric conductivity and an ultrasonic wave propagation speed of the hydrochloric acid aqueous solution by referring to a table made beforehand based on a relation among hydrochloric acid concentration, aluminum ion concentration, a temperature, a liquid electric conductivity and a liquid ultrasonic wave propagation speed. Then, the concentration was maintained constant by performing control to adjust the added quantity of the hydrochloric acid stock solution and water successively.

(8) Alkali Etching Treatment

The aluminum plate was subjected to alkali etching treatment by spraying aqueous solution containing 5 wt % of NaOH and 0.5 wt % of aluminum ions at a liquid temperature of 35° C. to the aluminum plate. The aluminum plate was dissolved by 0.15 g/m². Concentration of etching solution was calculated based on a temperature, specific gravity and an electric conductivity by referring to a table made beforehand based on a relation among NaOH concentration, aluminum ion concentration, a temperature, specific gravity and liquid electric conductivity, and maintained constant by adding water and 48 wt % of NaOH aqueous solution based on feedback control. Then, washing was carried out.

(9) Acid Etching Treatment

The aluminum plate was subjected to acid etching treatment by using sulfuric acid (sulfuric acid concentration 300 g/L, and aluminum ion concentration 15 g/L) as an acid etching solution, and spraying this to the aluminum plate from a spray pipe at a temperature of 80° C. for 8 sec. Concentration of the acid etching solution was calculated based on a temperature, specific gravity and an electric conductivity by referring to a table made beforehand based on a relation among sulfuric acid concentration, aluminum ion concentration, a temperature, specific gravity and liquid electric conductivity, and maintained constant by adding water and 50 wt % of sulfuric acid aqueous solution based on feedback control. Then, washing was carried out.

(Method of Graining Treatment B)

The method of graining treatment A was repeated except that in the above treatment (1), an abrasive having an average particle diameter of 50 μm was used, five nylon brushes each having a bristle diameter of 0.57 mm were used, and that the load of the driving motor was controlled so as to obtain an Ra of 0.58 μm.

(Method of Graining Treatment C)

The method of graining treatment A was repeated except that in the above treatment (1), the nylon brushes each had a bristle diameter of 0.25 mm, a pumice having an average particle diameter of 10 μm was used as the abrasive, and that the load of the driving motor was controlled so as to obtain an Ra of 0.35 μm.

(Method of Graining Treatment D)

An aluminum plate was prepared as in the above except that the Cu content was changed to 0.02 wt % in the aluminum plate described above. The thus obtained aluminum plate was used to perform the method of graining treatment A except that in the above treatment (4), the temperature of the aqueous solution of nitric acid was changed to 35° C. and the total quantity of electricity at the anode side was changed to 230 C/dm².

(Method of Graining Treatment E)

The method of graining treatment A was repeated except that the amount of the aluminum plate dissolved was 0.3 g/m² in the above treatment (5).

(Method of Graining Treatment F)

The method of graining treatment A was repeated except that the amount of the aluminum plate dissolved was 0.05 g/m2 in the above treatment (8).

(Method of Graining Treatment G)

The method of graining treatment A was repeated except that the amount of the aluminum plate dissolved was 0.5 g/m² in the above treatment (8).

(Method of Graining Treatment H)

The method of graining treatment A was repeated except that the above treatments (7) (8) and (9) were not performed.

(Method of Graining Treatment I)

The method of graining treatment A was repeated except that the above treatment (1) was not performed.

(Method of Graining Treatment J)

The method of graining treatment A was repeated except that the above treatments (4) (5) and (6) were not performed.

<Formation of Hydrophilic Layer>

(Method of Providing a Hydrophilic Layer a)

The hydrophilic layer providing method to be described below is sequentially performed after the graining treatment to thereby obtain an aluminum support having a hydrophilic layer formed on the surface thereof.

(10) Anodizing Treatment

The aluminum plate was subjected to anodizing treatment by using aqueous solution (containing aluminum ion 0.5 wt %) of oxalic acid concentration 50 g/L as an anodizing solution at a temperature of 30° C. for 150 sec., thus forming an anodized layer. Concentration of the anodizing solution was calculated based on a temperature, specific gravity and an electric conductivity by referring to a table made beforehand based on a relation among oxalic acid concentration, aluminum ion concentration, a temperature, specific gravity and liquid electric conductivity, and maintained constant by adding water and oxalic acid based on feedback control. Then, washing was carried out by spraying.

(11) Pore Widening Treatment

The aluminum plate after the anodizing treatment was subjected to pore widening treatment by dipping it in NaOH aqueous solution of pH 13, at a temperature of 5⁰° C. for 1 min. Then, washing was carried out.

(12) Sealing Treatment

The aluminum plate was dipped into an aqueous solution containing 1 wt % of a colloidal silica (SNOWTEX ST-N made by Nissan Chemical Industries, Ltd., particle size of about 20 nm) at 70° C. for 14 seconds and then washed with water.

(13) Surface Hydrophilic Treatment

Surface hydrophilic treatment was carried out by treating the aluminum plate in aqueous solution of 3rd sodium silicate concentration 2.5 wt % at a temperature of 70° C. for 12 sec.

Then, the plate was washed with water, and dried. Thus, an aluminum support was obtained.

(Method of Providing a Hydrophilic Layer b)

The method of providing a hydrophilic layer a was repeated except that the dipping time was changed to 2 min in the above treatment (11).

(Method of Providing a Hydrophilic Layer c)

The anodizing treatment (10) in the method of providing a hydrophilic layer a was replaced by the following treatment:

The aluminum plate was anodized under the conditions of a sulfuric acid concentration of 170 g/L (inclusive of 0.5 wt % of aluminum ion), a current density of 5A/dm², a temperature of 30° C. and 70 seconds and washed with water. Then, the aluminum plate was dipped into an aqueous solution of sodium hydroxide (pH 13) at a temperature of 30° C. for 30 seconds and washed with water.

Then, the treatments (12) and (13) in the method of providing a hydrophilic layer a were performed.

(Method of Providing a Hydrophilic Layer d)

The method of providing a hydrophilic layer a was repeated except that the anodizing time was changed to 120 sec in the treatment (10) mentioned above and the dipping time was changed to 3 min in the above treatment (11).

(Method of Providing a Hydrophilic Layer e)

The method of providing a hydrophilic layer c was repeated except that the treatment with NaOH aqueous solution was not performed.

2. Measurement of Thermal Conductivity of Hydrophilic Layer in Thickness Direction

For the aluminum support obtained above, the thermal conductivity of a hydrophilic layer in its thickness direction was measured by the method described below.

First, two other aluminum supports which are different from the aluminum support in each of Examples and Comparative Examples only in the thickness of the hydrophilic layer were prepared for each of Examples and Comparative Examples. In other words, aluminum supports which are different only in the thickness of the hydrophilic layer were prepared as in the aluminum supports in Examples and Comparative Examples except that the anodizing time in the method of providing a hydrophilic layer described above was reduced by half or doubled.

Then, sets of three aluminum supports which are different only in the thickness of the hydrophilic layer were subjected to the measurement of thermal conductivity using a device shown in FIG. 3. The following equation [1] was used to calculate the thermal conductivity in the thickness direction of each hydrophilic layer. The measurement was performed at 5 points on a sample and the average was used.

The results are shown in Tables 2 and 3.

$$\frac{( {T}_{r} - {T}_{b} )}{( {T}_{r} - {T}_{t} )} = ( \frac{4 {K}_{1} {r}_{1}}{{K}_{t f} {A}_{3}} ) t + ( 1 + ( \frac{4 {K}_{1} {r}_{1}}{{K}_{2} {A}_{2}} ) {t}_{2} + ( \frac{ {K}_{1} {r}_{1}}{{K}_{4} {r}_{1}} ) ) \qquad [ 1 ]$$

3. Measurement of AD Weight (Weight Per Unit Area of Anodized Layer)

The hydrophilic layer (including the anodized layer) of each aluminum support was dissolved in accordance with JIS H8688-1998 and the weight per unit area was measured by a method commonly called Mason method. In the measurement, five specimens each having a dimension of 20 cm×10 cm were used and the average of the measurements was regarded as the AD weight. The standard deviation was 0.03 or less.

The results are shown in Tables 2 and 3.

4. Measurement of Thickness (t) of Hydrophilic Layer

The aluminum support was bended and the lateral surface (usually fracture surface) of a crack produced during the bending operation was observed using a ultra-high resolution SEM (Hitach S-900). The observation was performed at a magnification of 50,000 at a relatively low acceleration voltage of 12 kV without performing the vapor deposition for imparting the conductivity. The average of the measurements obtained from 50 sections extracted at random was regarded as the thickness (t) of the hydrophilic layer. The standard deviation was within ±10%.

The results are shown in Tables 2 and 3.

5. Density Measurement

The density (d) of each hydrophilic layer (including each anodized layer) was determined from the AD weight (m) and the thickness (t) of each water layer obtained in 3 and 4 above, by using the following equation:

d [g/cm³]=m[g/m²]/t[μm]

The results are shown in Tables 2 and 3.

6. Porosity Measurement

The porosity of each hydrophilic layer (including each anodized layer) was determined from the density (d) obtained above, by the following equation:

Porosity (%)=(1-(d/3.98))×100

Note that 3.98 is a density (g/cm³) of aluminum oxide according to “Kagaku Binran (Handbook of Chemistry)” (edited by The Chemical Society of Japan, Maruzen).

The results are shown in Tables 2 and 3.

7. Measurement of Amount of Silicon Atom Adsorbed

The amount of silicon atom adsorbed on the surface of each aluminum support was measured by the calibration curve method using a fluorescent X-ray analyzer. A sodium silicate aqueous solution containing a known amount of silicon atom was uniformly dribbled on the area (φ30 mm) of the aluminum support, which was dried and then used as a standard sample for preparing a calibration curve.

The conditions of the fluorescent X-ray analysis of Si are as follows:

Fluorescent X-ray analyzer: RIX3000 made by Rigaku Corporation; X-ray tube: Rh; measurement spectrum: Si-Kα; tube voltage: 50 kV; tube current: 50 mA; slit: coarse; analyzing crystal: RX4; detector: F-PC; area analyzed: φ30 mm; peak position (2θ): 144.75 deg.; background (2θ): 140.70 deg. and 146.85 deg.; cumulative time: 80 seconds/sample.

The results are shown in Tables 2 and 3.

8. Preparation of Presensitized Plate

A presensitized plate was prepared by forming an image recording layer described below on each support for a lithographic printing plate obtained above.

Each presensitized plate was prepared by providing an undercoat layer and a photosensitive layer whose compositions are described below, on each aluminum support obtained above.

The undercoat layer coating solution with the following composition was coated on each support described above and dried at 80° C. for 15 seconds. The coated quantity after drying was 15 mg/m².

< Composition of undercoat layer coating solution >

| | | |
|---|---|---|
| High-molecular compound described below | 0.3 | g |
| Methanol | 100 | g |
| Water | 1 | g |

| | | |
|---|---|---|
| | | Mw 28,000 |
| 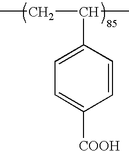 | 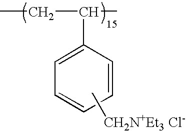 | |

Furthermore, a photosensitive layer coating solution with the following composition was coated on the undercoat layer with a bar coater and a photosensitive layer was formed by drying the photosensitive layer with a hot-air type drying device at 140° C. for 60 seconds to obtain a presensitized plate. The coated quantity after drying was 1.0 g/m².

< Composition of photosensitive layer coating
solution >

| | | |
|---|---|---|
| Capric acid | 0.03 | g |
| Specified copolymer later described | 0.75 | g |
| m, p-cresol novolak resin (m/p ratio = 6/4, weight | 0.25 | |
| average molecular weight 3,500, containing 0.5 wt % of | | |
| unreacted cresol) | | |
| p-toluenesulfonic acid | 0.003 | g |
| Tetrahydrophthalic anhydride | 0.03 | g |
| Cyanine dye A expressed by the structural formula | 0.017 | g |
| shown below | | |
| Dye prepared by setting a counter ion of Victorian | 0.015 | g |
| pure blue BOH as 1-naphthalenesulfonic acid anion | | |
| Fluorine-containing surfactant (Megafac F-177, made | 0.05 | g |
| by Dainippon Ink And Chemicals, Incorporated) | | |
| γ-butyrolactone | 10 | g |
| Methyl ethyl ketone | 10 | g |
| 1-methoxy-2-propanol | 1 | g |

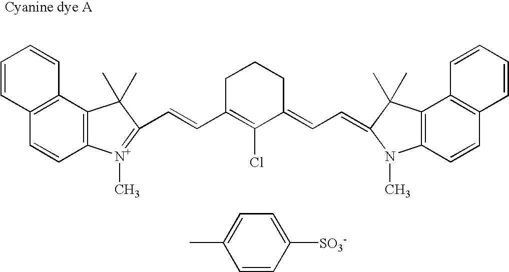

<Specified Copolymer>

Methacrylic acid of 31.0 g (0.36 mol), ethyl chloroformate of 39.1 g (0.36 mol) and acetonitrile of 200 mL were put into a three neck flask of 500 mL volume provided with a stirrer, a cooling tube and a dropping funnel and a mixture thereof was stirred while cooling the mixture with an ice water bath. Triethylamine of 36.4 g (0.36 mol) was dropped to the mixture with the dropping funnel in about one hour. After the dropping was over, the ice water bath was removed and the mixture was stirred at room temperature for 30 minutes.

p-aminobenzenesulfonamide of 51.7 g (0.30 mol) was added to the reaction mixture and the mixture was stirred for one hour while heating the mixture with an oil bath at 70° C. After the reaction was over, the mixture was added to water of 1 liter with stirring and the resultant mixture was stirred for 30 minutes. The deposit was filtered, to which water of 500 mL was added to obtain a slurry, this slurry was then filtered, and a white solid of N-(p-aminosulfonylphenyl)methacrylamide was obtained by drying the resultant solid (yield 46.9 g).

Next, N-(p-aminosulfonylphenyl)methacrylamide of 4.61 g (0.0192 mol), ethyl methacrylate of 2.94 g (0.0258 mol), acrylonitrile of 0.80 g (0.015 mol) and N, N-dimethylacetoamide of 20 g were supplied to a three neck flask of 200 mL volume provided with a stirrer, a cooling tube and a dropping funnel, and the mixture was stirred while heating the solution at 65° C. with a warm water bath. An azo polymerization initiator “V-65” (made by Wako Pure Chemical Industries, Ltd.) expressed by the following formula of 0.15 g was added to this mixture and the mixture was stirred for two hours while it was kept at 65° C. in the gas flow of nitrogen. A mixture of N-(p-aminosulfonylpheyl)methacrylamide of 4.61 g, ethyl methacrylate of 2.94 g, acrylonitrile of 0.80 g, N,N-dimethylacetoamide and an azo polymerization initiator “V-65” expressed by the following formula of 0.15 g was further dropped to the reaction product with a dropping funnel over two hours. After the dropping was over, the resultant mixture was further stirred at 65° C. for two hours. After the reaction was over, methanol of 40 g was added to the mixture and was cooled, the resultant mixture was added to water of 2 liters with stirring, after the mixture was stirred for 30 minutes, a deposit filtered and a white solid of the specified copolymer of 15 g was obtained by drying the deposit.

As the weight average molecular weight of the resultant specified copolymer was measured with a gel permeation chromatography, it was 53,000 (in polystyrene standard).

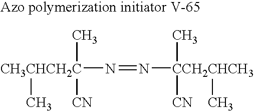

The thus obtained presensitized plates were subjected to the respective measurements and tests described below and the results were shown in Tables 2 and 3. Note that the symbol “−” in Tables 2 and 3 shows that there is no corresponding structure.

9. Average Aperture Diameter of a Grained Structure With Medium Undulation

The thermosensitive layer of each presensitized plate obtained above was dissolved and removed by using γ-butyrolactone and the support surface was exposed. Then, the surface of the support was photographed at a magnification of 2,000 from right above with an SEM. Next, in SEM micrograph obtained, 50 pits of a grained structure with medium undulation (pits of medium undulation) in which circumferences of the pits were annularly connected were extracted, aperture diameters were determined by reading the diameters of the pits, and an average diameter aperture was calculated.

10. Average Aperture Diameter of a Grained Structure With Small Undulation

The thermosensitive layer of each presensitized plate obtained above was dissolved and removed by using γ-butyrolactone and the support surface was exposed. Then, the surface of the support for a lithographic printing plate was photographed at a magnification of 50,000 from right above with an SEM. In an SEM micrograph obtained, 50 pits of the grained structure with small undulation (pits of small undulation) were extracted, the aperture diameters were determined by reading the diameters of the pits and an average aperture diameter was calculated.

11. Average of Ratio of Depth to Aperture Diameter of a Grained Structure With Small Undulation

The average of ratio of depth to aperture diameter of a grained structure with small undulation was obtained as follows. A broken-out section of the support was photographed at a magnification of 50,000 with a high resolution SEM. In an SEM micrograph obtained, 20 pits of small undulation with aperture diameter 0.5 μm or less were extracted, the ratios were obtained by reading the aperture diameters and depths, and an average ratio was calculated.

In Tables 2 and 3, the average ratio of depth to aperture diameter of a grained structure with small undulation is represented by “average ratio”.

12. Average Wavelength of Large Undulation

The photosensitive layer of each presensitized plate obtained above was dissolved and removed by using γ-butyrolactone and the support surface was exposed. Then, the surface of the support for a lithographic printing plate was observed at a magnification of 2,000 with an SEM, T-20 made by JEOL Ltd. Thirty asperity components with large undulation were read in a horizontal direction and in a direction vertical thereto, respectively and the average of the measurements was regarded as the average wavelength.

13. Sensitivity Evaluation of Presensitized Plate

A device, TrenndSetter 3244 made by CREO Inc. was used to expose the presensitized plates described above with varying printing plate energies (exposure outputs), which is followed by a development treatment by a development process described below. The printing plate energy of the minimal laser beam just before an abrupt increase of the amount of a residual layer, namely, that of the minimal laser beam with which an image can be formed was used as a sensitivity index.

The results on printing plate energy were shown in Tables 2 and 3. A smaller exposure amount (lower printing plate energy) indicates that development requires a smaller exposure amount and sensitivity is higher, whereas a larger exposure amount indicates that development requires a larger exposure amount and sensitivity is lower.

Development process: A development treatment was performed under standard operating conditions using an automatic processor 900NP containing a PS plate developer DT-1 (developer containing no Si) made by Fuji Photo Film Co., Ltd.

14. Preparation of Lithographic Printing Plate

Image exposure and development treatment were performed on each presensitized plate obtained above in the following methods and a lithographic printing plate was obtained.

Image exposure was performed on a presensitized plate at a main scanning speed of 5 m/sec and printing plate energy of 140 mJ/cm², with CREO Inc.—made TrenndSetter 3244 equipped with a semiconductor laser of output 500 mW, wavelength 830 nm and beam diameter 17 μm (1/e²) Thereafter, development treatment was performed on the presensitized plate with an alkali developer in which the compound (a) was added to an aqueous solution 1L containing 5.0 wt % of potassium salt having D-sorbitol/potassium oxide K₂O which was a combination of non-reducing sugar and base and OLFINE AK-02 (made by Nissin Chemical Industry Co., Ltd.) 0.015 wt %. This treatment was performed at a development temperature of 30° C. for 12 seconds with an automatic processor PS900NP (made by Fuji Photo Film Co., Ltd.) filled with the aforementioned developer. After the development treatment was over, water washing treatment was then performed, treatment with gum (FP-2W) or the like was performed, and a lithographic printing plate with plate making completed was obtained. Note that, in place of the compound (a), even when an alkali developer containing the following compound (b) or (c) at the same amount as that of the compound (a) was used, development treatment could be performed in the same manner.

<Compounds (a) to (c)>

Compound (a): C₁₂H₂₅N (CH₂ CH₂ COONa)₂

Compound (b): C₁₂H₂₅O (CH₂ CH₂ O)₇ H

Compound (c): (C₆H₁₃)₂ CHO (CH₂ CH₂ O)₂₀ H

15. Evaluation of Lithographic Printing Plate (Scum Resistance)

Printing was performed using each lithographic printing plate prepared above, with magenta ink of DIC-GEOS (s) in a printing machine DAIYA-F-2 (made by Mitsubishi Heavy Industries, Ltd.) and the scum of a blanket was visually inspected after printing of 10,000 sheets was carried out. The results were shown in Tables 2 and 3. The scum resistance was evaluated by five levels including \mathring{∘}, ◯\mathring{∘}, ◯, Δ, and × in the order of scum increase.

16. Evaluation of Lithographic Printing Plate (Press Life)

Printing was performed using each lithographic printing plate prepared above, with black ink of DIC-GEOS (N) made by Dainippon Ink And Chemicals, Incorporated in a printing machine Lithrone made by Komori Corporation, and press life was evaluated by the number of the printed sheets at a time when a visual inspection recognizes that the density of a solid image begins to decrease.

The results were shown in Tables 2 and 3.

TABLE 2-(1)

| | | | A grained | | | | | | | |
|---|---|---|---|---|---|---|---|---|---|---|
| | | | structure with | | | | | | | |
| | Average | Average aperture | small undulation | | | | | | | Amount |
| | wavelength | diameter of a | Average | | Hydrophilic layer | | | | | of Si |
| | of large | grained structure | aperture | | Thermal | | | AD | Thickness of | atom |
| | undulation | with medium | diameter | Average | conductivity | density | porosity | weight | hydrophilic | adsorbed |
| | (μm) | undulation (μm) | (μm) | ratio | (W/m · K) | (g/cm³) | (%) | (g/m²) | layer (μm) | (mg/m²) |
| Example 1 | 10 | 1.0 | 0.2 | 0.24 | 0.2 | 2.00 | 50 | 5.0 | 1.1 | 7.9 |
| Example 2 | 25 | 1.0 | 0.2 | 0.24 | 0.2 | 2.00 | 50 | 5.0 | 1.1 | 7.9 |
| Example 3 | 5 | 1.0 | 0.2 | 0.24 | 0.2 | 2.00 | 50 | 5.0 | 1.1 | 7.9 |
| Example 4 | 10 | 2.0 | 0.2 | 0.24 | 0.2 | 2.00 | 50 | 5.0 | 1.1 | 6.4 |
| Example 5 | 10 | 0.6 | 0.2 | 0.24 | 0.2 | 2.00 | 50 | 5.0 | 1.1 | 6.4 |
| Example 6 | 10 | 1.0 | 0.05 | 0.1 | 0.2 | 2.00 | 50 | 5.0 | 1.1 | 8.4 |
| Example 7 | 10 | 1.0 | 0.5 | 1.0 | 0.2 | 2.00 | 50 | 5.0 | 1.1 | 6.2 |
| Example 8 | 10 | 1.0 | 0.2 | 0.24 | 0.05 | 1.05 | 70 | 4.2 | 1.0 | 12.4 |
| Example 9 | 10 | 1.0 | 0.2 | 0.24 | 0.5 | 3.15 | 20 | 4.0 | 1.0 | 4.5 |

TABLE 2-(2)

| | Sensitivity | Scum | Press life |
|---|---|---|---|
| | (mJ/cm²) | resistance | (10,000 sheets) |
| Example | 70 | ◯⊚ | 10 |
| 1 | | | |
| Example | 75 | ◯ | 9 |
| 2 | | | |
| Example | 65 | ⊚ | 10.5 |
| 3 | | | |
| Example | 70 | ⊚ | 11 |
| 4 | | | |
| Example | 70 | ◯⊚ | 10 |
| 5 | | | |
| Example | 70 | ◯ | 10 |
| 6 | | | |
| Example | 70 | ⊚ | 10 |
| 7 | | | |
| Example | 50 | ⊚ | 10 |
| 8 | | | |
| Example | 70 | ⊚ | 10 |
| 9 | | | |

TABLE 3-(1)

| | | | A grained | | | | | | | |
|---|---|---|---|---|---|---|---|---|---|---|
| | | | structure with | | | | | | | |
| | Average | Average aperture | small undulation | | | | | | | Amount |
| | wavelength | diameter of a | Average | | Hydrophilic layer | | | | | of Si |
| | of large | grained structure | aperture | | Thermal | | | AD | Thickness of | atom |
| | undulation | with medium | diameter | Average | conductivity | density | porosity | weight | hydrophilic | adsorbed |
| | (μm) | undulation (μm) | (μm) | ratio | (W/m · K) | (g/cm³) | (%) | (g/m²) | layer (μm) | (mg/m²) |
| Com- | 10 | 1.0 | 0.2 | 0.24 | 0.03 | 0.80 | 80 | 3.5 | 0.8 | 17.2 |
| parative | | | | | | | | | | |
| Example 1 | | | | | | | | | | |
| Com- | 10 | 1.0 | 0.2 | 0.24 | 0.7 | 3.5 | 15 | 4.3 | 1.1 | 4.2 |
| parative | | | | | | | | | | |
| Example 2 | | | | | | | | | | |
| Com- | 10 | 1.0 | — | — | 0.2 | 2.0 | 50 | 5.0 | 1.1 | 6.8 |
| parative | | | | | | | | | | |
| Example 3 | | | | | | | | | | |
| Com- | — | 1.0 | 0.2 | 0.24 | 0.2 | 2.0 | 50 | 5.0 | 1.1 | 7.5 |
| parative | | | | | | | | | | |
| Example 4 | | | | | | | | | | |
| Com- | 10 | — | 0.2 | 0.24 | 0.2 | 2.0 | 50 | 5.0 | 1.1 | 7.0 |
| parative | | | | | | | | | | |
| Example 5 | | | | | | | | | | |

TABLE 3-(2)

| | Sensitivity | Scum | Press life |
|---|---|---|---|
| | (mJ/cm²) | resistance | (10,000 sheets) |
| Comparative | 50 | X | 10 |
| Example 1 | | | |
| Comparative | 120 | ◯ | 10 |
| Example 2 | | | |
| Comparative | 70 | ◯ | 2 |
| Example 3 | | | |
| Comparative | 70 | ◯ | 5 |
| Example 4 | | | |
| Comparative | 70 | Δ | 5 |
| Example 5 | | | |

The presensitized plate of the present invention has a hydrophilic layer whose thermal conductivity in the thickness direction is 0.05 to 0.5 W/(m·K). Therefore, when an infrared laser has a low light exposure or even when a developer has a low fluidity, the image recording layer to be exposed is highly soluble in the developer, which results in higher sensitivity, wider development latitude and decrease of residual layer in low light exposure. Further, scum hardly develops at non-image area.

In the presensitized plate of the present invention obtained by forming a hydrophilic layer having a thermal conductivity within a specified range, on an aluminum support according to the present invention having a grained shape in a triple structure in which grained structures having specified average wavelength (aperture diameters) are superimposed, and then forming a specified image recording layer on the hydrophilic layer, heat can be efficiently used for image formation. The presensitized plate is highly sensitive and when processed into a lithographic printing plate, exhibits long press life, and hardly generate scum at non-image area.

What is claimed is:

1. A presensitized plate comprising:
an aluminum support which has a grain shape in a structure in which a grained structure with large undulation of 2 to 30 μm average wavelength, a grained structure with medium undulation of 0.5 to 5 μm average aperture diameter and a grained structure with small undulation of 0.01 to 0.5 μm average aperture diameter are superimposed and in which an average ratio of depth to aperture diameter of the grained structure with small undulation whose average aperture diameter is 0.01 to 0.5 μm is 0.1 to 1.0;
a hydrophilic layer whose thermal conductivity is 0.05 to 0.5 W/(m·K) and which is formed on the aluminum support; and
an image recording layer which includes a water-insoluble and alkali-soluble resin and an infrared absorbent, in which solubility in an alkali aqueous solution is increased by heating, and which is formed on the hydrophilic layer.

2. A presensitized plate comprising:
an aluminum support which has a grain shape in a structure in which a grained structure with large undulation of 2 to 30 μm average wavelength, a grained structure with medium undulation of 0.5 to 5 μm average aperture diameter and a grained structure with small undulation of 0.01 to 0.5 μm average aperture diameter are superimposed and in which an average ratio of depth to aperture diameter of the grained structure with small undulation whose average aperture diameter is 0.01 to 0.5 μm is 0.1 to 1.0;
a hydrophilic layer which has a density ranging from 1.0 to 3.2 g/cm³ or a porosity ranging from 20 to 70% and which is formed on the aluminum support; and
an image recording layer which includes a water-insoluble and alkali-soluble resin and an infrared absorbent, in which solubility in an alkali aqueous solution is increased by heating, and which is formed on the hydrophilic layer.

3. The presensitized plate according to claim 1, wherein the aluminum support is obtainable by subjecting an aluminum or aluminum alloy plate to mechanical graining treatment, chemical etching treatment in an alkali aqueous solution, desmutting treatment with an acid, electrochemical graining treatment using an electrolyte containing nitric acid, electrochemical graining treatment using an electrolyte containing hydrochloric acid, chemical etching treatment in an alkali aqueous solution and desmutting treatment with an acid in this order.

4. The presensitized plate according to claim 2, wherein the aluminum support is obtainable by subjecting an aluminum or aluminum alloy plate to mechanical graining treatment, chemical etching treatment in an alkali aqueous solution, desmutting treatment with an acid, electrochemical graining treatment using an electrolyte containing nitric acid, electrochemical graining treatment using an electrolyte containing hydrochloric acid, chemical etching treatment in an alkali aqueous solution and desmutting treatment with an acid in this order.

5. The presensitized plate according to claim 1, wherein the hydrophilic layer is an anodized layer formed by an anodizing treatment.

6. The presensitized plate according to claim 2, wherein the hydrophilic layer is an anodized layer formed by an anodizing treatment.

7. The presensitized plate according to claim 5, wherein the hydrophilic layer is subjected to a hydrophilic surface treatment with an aqueous solution of an alkali metal silicate.

8. The presensitized plate according to claim 6, wherein the hydrophilic layer is subjected to a hydrophilic surface treatment with an aqueous solution of an alkali metal silicate.
